(19) United States
(12) Patent Application Publication
(10) Pub. No.: US 2021/0216674 A1
(43) Pub. Date: Jul. 15, 2021

(54) Chained Iterative Application of Computer Aided Generative Design for Optimized Geometries

(71) Applicant: PTC INC., BOSTON, MA (US)

(72) Inventors: Jonathan Hiller, Boulder, CO (US); Jesse C. Blankenship, Southampton, NY (US)

(21) Appl. No.: 17/215,279

(22) Filed: Mar. 29, 2021

Related U.S. Application Data
(63) Continuation of application No. PCT/US19/53916, filed on Sep. 30, 2019.
(60) Provisional application No. 62/738,714, filed on Sep. 28, 2018.

(51) Int. Cl. G06F 30/12; G06F 30/20

(52) U.S. Cl. CPC G06F 30/12; G06F 30/20

(57) ABSTRACT

Generative design uses artificial intelligence to automatically create optimal designs from a set of system design requirements. A generative design system receives user-supplied design requirements and generates an optimized geometry by chaining iterative applications of computer aided generative design. In one aspect, the system uses the output of a first generative design process as a requirement of or as part of the design requirements for a second generative process, with or without intervening user input. In another aspect, the system enables designers to incrementally or iteratively specify and edit design requirements such that each resulting geometry is derived from a previously or most recently generated optimized geometry and optionally updated design requirements. The system, by using or reusing outputs and/or data from previous design iterations can produce subsequent designs more efficiently and quickly.

### RELATED APPLICATIONS

The subject matter of this application is related to U.S. Provisional Application No. 62/738,714, filed on Sep. 28, 2018, Patent Cooperation Treaty Application No. PCT/US19/53916, filed on Sep. 30, 2018, U.S. application Ser. No. 15/079,815 filed Mar. 24, 2016, now U.S. Pat. No. 10,042,817, and U.S. Provisional Application No. 62/145,350, filed Apr. 9, 2015, all of which applications are incorporated herein by reference in their entireties.

### BACKGROUND OF THE INVENTION

In the current iterative boundary representation (BREP) computer-aided design (CAD) paradigm a designer specifies the shape of each part and then must verify its functionality, both individually and in the context of the assembly. If the functionality is not confirmed, the designer must iterate the shape and the process repeats itself. There is no way around the fact that this is a “guess and check” process, although good intuition on the part of the human designer means good “guesses” for relatively simple projects and few, if any, iterations are required. But in the drive for increased performance, the allowable target area becomes rapidly smaller and harder to guess intuitively. Add a combination of complex environments of many interdependent parts, performance requirements across multiple domains of physics, coupled spatial constraints, and shape requirements imposed by the desired manufacturing method and even the best designer will be swamped trying to balance all the competing objectives in their head at once. At some point the human brain can no longer scale. Moreover, conventional systems rely greatly on human expertise and skill to refine geometries for objects. A designer, using her experience and/or via trial and error, has to create several new geometries from scratch in order to generate a finalized geometry for an object that approximates, but does not always meet, the optimization criteria for the object. If a requirement changes, the entire process begins again. For example, using conventional systems, every time a designer makes any change to an object being modeled (for example, load constraints, force direction, placement of a bolt, or manufacturing material), the designer has to restart the process of generating a geometry from scratch. Every time the designer makes an edit or tweak to the design parameters, conventional systems discard any previously generated geometries and instead create a new geometry corresponding to the updated parameters. This leads, for example, to several inefficiencies of time, materials, computing resources, and networking resources.

### SUMMARY OF THE INVENTION

Generative design uses artificial intelligence to automatically create optimal designs from a set of system design requirements. A generative design system receives user-supplied design requirements and generates an optimized geometry by chaining iterative applications of computer aided generative design. Design requirements can include, for example: design objectives, assembly context, fixed geometry, load cases, materials, and manufacturing processes. Design objectives can include, for example: optimize topology, mesostructure, and simulate. In one aspect, the system uses the output of a first generative design process as a requirement of or as part of the design requirements for a second generative process, with or without intervening user input.

In another aspect, the system enables designers to incrementally or iteratively specify and edit design requirements such that each resulting geometry is derived from a previously or most recently generated optimized geometry and optionally updated design requirements. For example, a designer can initiate a user interface (UI) mode with the system by specifying certain design requirements. The designer can then interact with the system by setting up parameters, getting visual results back quickly, and iterating to obtain a desired design. The designer, therefore, is not required to restart the process for generating an optimized geometry from the beginning each time a change is made to the design requirements. The system, by using or reusing outputs and/or data from previous design iterations can produce subsequent designs more efficiently and quickly.

In various embodiments, the system can be integrated with one or more other BREP CAD tools. For example, the system can receive a set of inputs formulated within a CAD platform, perform processing to generate an optimized topology for the received set of inputs, and return the shape results to the CAD platform. In another example, a designer can initiate a UI mode wherein inputs from a CAD platform to the system are calculated upon entry and loaded into the system memory. The designer can interact with the system to set up parameters, for example, related to design requirements, receive visual results based on the parameters, and iterate to get a desired design. Upon exiting the UI mode, the system processes the results back into the CAD platform's native representation. In this manner, the designer is provided with a superior and efficient design experience.

The system provides several benefits over conventional systems. The system enables a designer to build a highly complex shape procedurally from other solid geometry. The system is useful for a modeling task where the number of surfaces or surface-to-surface calculations, for example, fillets, would severely affect the performance of traditional BREP systems. The system enables modeling where parametric changes to a design may result in topological changes. The system enables a user to express design intent via a tree structure of set-theoretic operations such as union, subtraction, and intersection. The system provides a mechanism for combining precise engineering geometry with freeform or algorithmic geometry. The system enables blending between complex shapes, blending at or larger than some feature sizes, and offsetting or shelling of complex shapes.

In various embodiments, a software and/or hardware system uses generative design paradigms where a designer specifies a required functionality of an entire part or assembly in response to which the system produces an optimal shape of the part or assembly. The use of generative design techniques takes human iterations and negotiations across the systems, design, modeling, analysis, and manufacturing departments out of the design process and pushes them earlier into the project requirements process. Changes to the requirements can cause the system to re-execute the entire automated process to produce updated designs. In the case the system cannot create an optimal design or shape based on a new combination of requirements, the user can be informed.

The system can enable a designer to iteratively refine optimized topologies of objects using generative design methodologies. In contrast to conventional systems discussed above, the system enables a designer to reuse previously generated optimized geometries to generate revised optimized geometries that correspond to updated design requirements. For example, a designer can generate an initial optimized geometry for a body object using an initial set of design/optimization criteria, including, for example, design parameters and a design recipe discussed below. The designer can then update a direction of force applied to a body object area. In response to the update, the system can generate an updated optimized geometry for the body object corresponding to the updated optimization criteria, such as the changed force direction, that is derived from the initial optimized geometry or any previous version of the generated optimized geometry. The system can enable designers to generate and/or regenerate geometrically unambiguous and optimized geometries by simply specifying updated parameters. No further user interaction, such as manual fine tuning, is necessarily required to generate corresponding optimized geometries.

The system can be configured to use generative design methodologies, and accordingly can be configured to generate geometries that optimize the amount or volume of materials used to print the geometries. This results in, for example, reduced costs of manufacturing materials, reduced time to manufacture the optimized geometries, reduced cost of manufacturing, and reduced weight without sacrificing the structural integrity of the generated geometry of a body object.

In one embodiment, a method can be performed by a computing system having at least one processor and a memory. The method can include: receiving a first set of user-supplied design requirements for a computer aided design geometry; executing a first generative design process to generate a first optimized geometry based on the first set of user-supplied design requirements; and executing a second generative design process to generate a second optimized geometry based on a second set of user-supplied design requirements for the computer aided design geometry and based on applying the first optimized geometry as a requirement for the second optimized geometry.

The method can further include: in response to presenting the first optimized geometry in a computer user interface, receiving the second set of user-supplied design requirements through the user interface. The method can be performed without receiving user input between the first and second generative design processes. The second set of user-supplied design requirements can be received in advance of executing the first generative design process.

The method can further include: performing a simulation on the first optimized geometry; and applying a result of the simulation as an input to the second generative design process. The first generative design process, the simulation, and the second generative design process can be performed according to a design recipe specified in advance of executing the first generative design process. The method can be performed without receiving user input between the first and second generative design processes.

The first optimized geometry can be applied as a three-dimensional geometric design requirement for the second optimized geometry. The first optimized geometry can be applied to limit the second optimized geometry to be wholly contained within the first optimized geometry. The first optimized geometry can be used to seed the second generative design process. The second set of user-supplied design requirements can include the first optimized geometry. Intermediate results from computations performed during execution of the first generative design process can be reused in the second generative design process to avoid repeating the computations. The first set of user-supplied design requirements and the second set of user-supplied design requirements may have one or more common design requirements and one or more differing design requirements.

In one embodiment, a method can be performed by a computing system having at least one processor and a memory. The method can include: receiving a first set of optimization criteria for a computer aided design geometry; generating a first optimized geometry using the received first set of optimization criteria; receiving a second set of optimization criteria for the computer aided design geometry; and generating a second optimized geometry using the generated first optimized geometry and the received second set of optimization criteria. The second set of optimization criteria can be received through a computer user interface in response to the first optimized geometry being presented in the user interface. The method can further include: performing a simulation on the first optimized geometry, wherein the second optimized geometry is generated further based on a result of the simulation.

The first optimized geometry can be applied as a three-dimensional geometric design requirement for generating the second optimized geometry. The first optimized geometry can be applied to limit the second optimized geometry to be wholly contained within the first optimized geometry. The first optimized geometry can be used to seed the generation of the second optimized geometry. The second set of optimization criteria can include the first optimized geometry. The first set of optimization criteria and the second set of optimization criteria may have at least one common optimization criterion.

The first set of optimization criteria or the second set of optimization criteria may include one or more of: geometry, materials, symmetry, optimization objectives, or shape. The first set of optimization criteria or the second set of optimization criteria may include an optimization objective selected from a group consisting of: minimize strain energy subject to volume fraction, minimize volume subject to material safety factor, minimize inverse minimum modal frequency subject to volume fraction, and minimize strain energy subject to minimum modal frequency. The computer aided design geometry may be associated with a constraint selected from a group consisting of: displacement, pinned joint, ball joint, planar slider, and linear slider. The computer aided design geometry can be associated with a load selected from a group consisting of: simple force, bearing force, rigid body movement, acceleration, deceleration, and pressure.

The first set of optimization criteria, the second set of optimization criteria, or both can be defined by design recipe having at least one generative design step and at least two stages wherein an output of an earlier stage is used as an input by a subsequent stage. Generating the first optimized geometry or generating the second optimized geometry can include one or more of: optimizing topology, applying mesostructure, and geometry simulation.

The methods can be performed by a computing system including the at least one processor and the memory, wherein the memory has instructions stored thereon that, when executed by the at least one processor, cause the computing system to perform any of the methods.

A non-transitory computer readable medium can have instructions stored thereon, wherein the instructions, when executed by the least one processor, cause the at least one processor to perform any of the methods.

### BRIEF DESCRIPTION OF THE DRAWINGS

FIG. 1 is a system diagram illustrating an example of a computing environment in which the system is utilized.

FIG. 2 is a block diagram showing some of the components typically incorporated in at least some of the computer systems and other devices on which the system operates.

FIG. 3 is a block diagram showing the components of the system.

FIGS. 4A-4G illustrate examples of results from the optimization framework run with different filters.

FIG. 5 is a flow diagram showing a process for generating optimized geometries by the system.

FIG. 6 is a block diagram showing input design requirements received by the system.

FIG. 7 is a block diagram depicting a process of generating an initial optimized geometry based on the received design requirements/parameters and/or a generative design recipe.

FIG. 8 is a block diagram depicting a process of generating a revised/updated optimized geometry based on a previous optimized geometry.

FIGS. 9A-9F illustrate examples of gyroid-based mesostructures/lattices and a bracket shaped body object generated using the gyroid-based mesostructures/lattices.

FIGS. 10A-10I illustrate examples of strut-based mesostructures/lattices and a bracket shaped body object generated using the strut-based mesostructures/lattices.

FIG. 11 illustrates example outputs from the optimization framework for different stages of a design recipe.

FIGS. 12-19 illustrate examples of other types of mesostructures/lattices.

FIGS. 20A-20D illustrate example user interfaces of the system.

### DETAILED DESCRIPTION

In the following description, references are made to various embodiments in accordance with which the disclosed subject matter can be practiced. Some embodiments may be described using the expressions one/an/another embodiment or the like, multiple instances of which do not necessarily refer to the same embodiment. Particular features, structures or characteristics associated with such instances can be combined in any suitable manner in various embodiments unless otherwise noted.

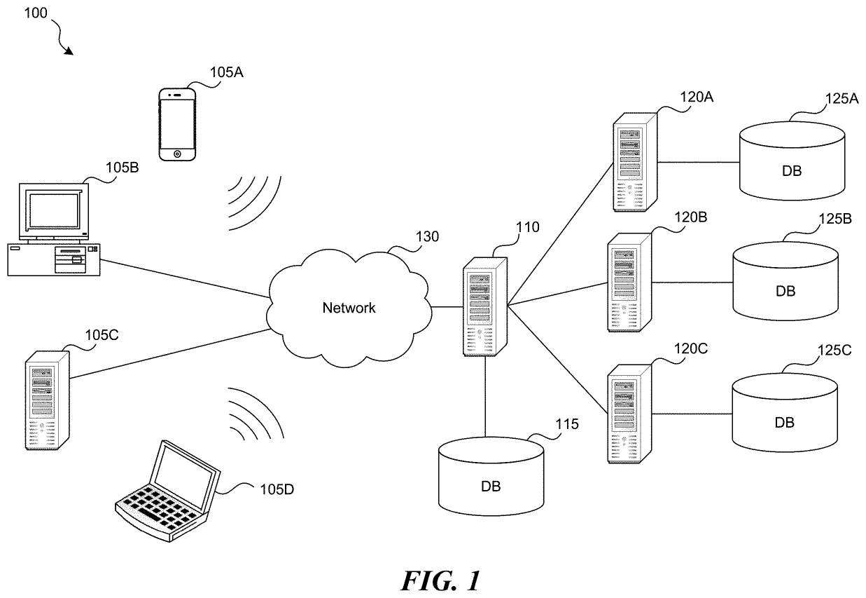

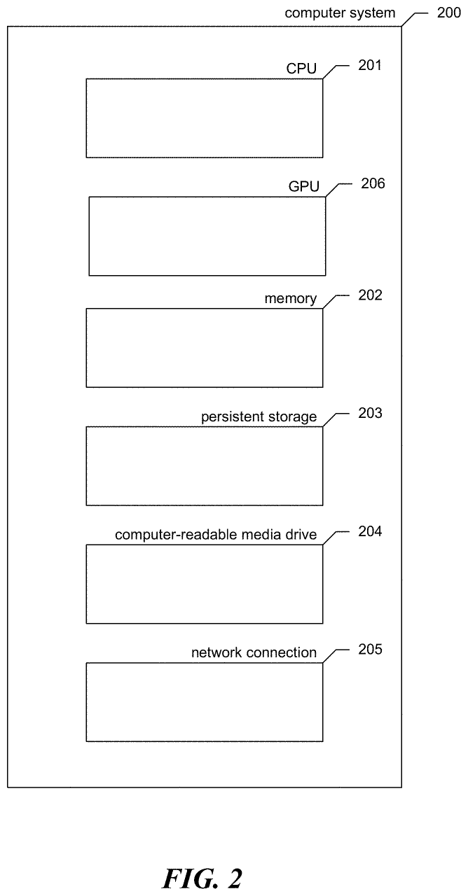

FIG. 1 is a system diagram illustrating an example of a computing environment 100 upon which a generative design system can be implemented. In some implementations, environment 100 includes one or more client computing devices 105A-D, such as the computer system 200 (FIG. 2). Client computing devices 105 can operate in a networked environment using logical connections through a network 130 to one or more other computers, such as a server computing device. One or more users can use client computing devices 105 to view, generate, edit/update, and/or print one or more optimized geometries based on certain design specifications. Design specifications can include, for example, shape, exclusion zone(s), inclusion zone(s), manufacturing material(s) (e.g., plastic, metal), manufacturing technique(s) (e.g., injection molding, 3D printing, casting/molding, computer manufacturing, multiple axis (e.g. 2 or 3 axis) machining, and efficient additive manufacturing), and load/force profile(s).

Server 110 can be an edge server that receives client requests (e.g., to create a new optimized topology) and coordinates fulfillment of those requests through other servers, such as servers 120A-C. In some implementations, server computing devices 110 and 120 can be computing systems, such as computer system 200 (FIG. 2). Though each server computing device 110 and 120 is displayed logically as a single server, server computing devices can each be a distributed computing environment encompassing multiple computing devices located at the same or at geographically disparate physical locations. In some implementations, each server 120 can correspond to a group of servers.

Client computing devices 105 and server computing devices 110 and 120 can each act as a server or client to other server/client devices. In several embodiments, the system can be distributed across one or more client computing devices 105 and/or servers 110/120A-C to increase efficiency of computations and/or decrease time to manufacture/generate optimized geometries. In some implementations, servers (110, 120A-C) connect to a corresponding database (115, 125A-C). As discussed above, each server 120 can correspond to a group of servers, and each of these servers can share a database or can have their own database. Databases 115 and 125 can store information such as object shapes, optimized topologies, load parameters, manufacturing materials, manufacturing techniques, and user data such as, user identifiers, name, and location. Though databases 115 and 125 are displayed logically as single units, databases 115 and 125 can each be a distributed computing environment encompassing multiple computing devices, can each be located within a corresponding server, or can be located at the same or at geographically disparate physical locations.

Network 130 can be a local area network (LAN) or a wide area network (WAN) but can also be or include other wired or wireless networks. Network 130 can be the Internet or some other public or private network. Client computing devices 105A-D can be connected to network 130 through a network interface, such as by wired or wireless communication. While the connections between server 110 and servers 120 are shown as separate connections, these connections can be any kind of local, wide area, wired, or wireless network, including network 130 or a separate public or private network.

FIG. 2 is a block diagram showing various components that can be incorporated in computer systems and other devices of the system 100. The computer systems and other devices 200 can include, for example, server computer systems, desktop computer systems, laptop computer systems, netbooks, mobile phones, personal digital assistants, televisions, cameras, automobile computers, and electronic media players. The computer systems and devices can include one or more of each of the following: a central processing unit (“CPU”) 201 for executing computer programs; a graphics processing unit (“GPU”) 206; a computer memory 202 for storing programs and data while they are being used, such as programs to operate the system 100 and associated data; an operating system including a kernel, device drivers; a persistent storage device 203, such as a hard drive or flash drive for persistently storing programs and data; a computer-readable media drive 204 such as a floppy, CD-ROM, or DVD drive, for reading programs and data stored on a computer-readable medium; and a network connection 205 for connecting the computer system to other computer systems to send and/or receive data, such as via the Internet or another network and its networking hardware, such as switches, routers, repeaters, electrical cables and optical fibers, light emitters and receivers, radio transmitters and receivers. While computer systems configured as described above are typically used to support the operation of the system, those skilled in the art will appreciate that the system can be implemented using devices of various types and configurations, and having various components.

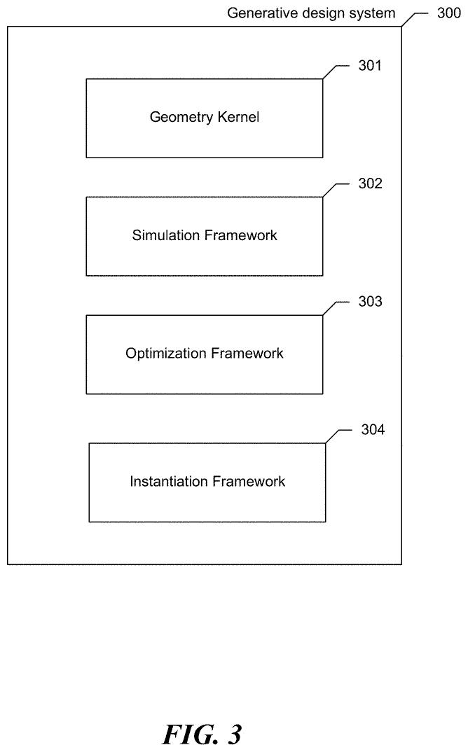

FIG. 3 is a block diagram showing logical components of a generative design system 300 for generating optimized geometries using generative design methodologies. The generative design system 300 can include one or more of: a geometry kernel 301, a simulation framework 302, an optimization framework 303, and an instantiation framework 304. The logical components can be configured to operate upon or in the system 100 and/or its various components.

Geometry Kernel

In accordance with one embodiment, a geometry kernel 301 receives optimization criteria and/or design requirements to generate an optimized geometry based on the received requirements. For example, the geometry kernel 301 can enable a user to specify data in a higher dimensional form that mathematically results in an unambiguous solid. The surfaces of that solid may be generated if desired (e.g., for visualization or for supporting current manufacturing toolchains), and the surfaces can be created on demand and discarded whenever they are out of date. The geometry kernel 301 can receive design requirements based on which optimized geometries are generated.

Optimization criteria and/or design requirements can include, for example, information about an optimization goal or problem, such as, design parameters and/or a design recipe. The optimization criteria and/or design requirements can include, for example, top level information about objectives or criteria of the optimization, the material properties to be utilized, and desired symmetry. The optimization criteria and/or design requirements can also include a description of interfacing geometry and relevant loads or constraints each interfacing geometry represents.

In accordance with one embodiment, there are two main structures of a design specification: a body and an assembly. In both structures, the concept of a body is common. A body object can include, for example, information about a material, geometric information such as shape, optimality criteria (for optional optimization) and a filter stack (optional).

Material information can describe material to be used to generate an optimized geometry. Material information can include, for example, a material's physical properties. Material information can be specified, for example, using a name field for presenting human-interpretable information. Material types can include, for example, isotropic, orthotropic, and anisotropic.

A body object can also contain geometric information in the form of, for example, shape objects. Shape objects can be categorized, for example, as primitives and composed. Shape objects can be identified using a name and can include a set of child density shape objects. Each density shape object can have, for example, a type, a descriptive name, a position such as x, y, z coordinates, a rotation angle, a rotation axis, a blending, and load cases. Transformations to density shape objects can be applied, for example, by position, rotation angle, and rotation axis.

Load cases, such as boundary conditions, can be specified at the level of the density shape object in the form of loads and constraints. Each shape can have a set of load case objects, where a maximum size of any of these sets within the shape's specification can determine the number of load cases to be considered for the optimization. An index in the set can be used to identify each load case. Each load case can specify multiple loads and/or constraints. In one example, force and moment can be applied. In another example, a linear slide with a force in the same direction can be applied. Forces can be added or accumulated). In various embodiments, constraints can supersede each other in the event of a conflict in degrees of freedom. Per-load case criteria can also be included, such as maximum displacement checks. In various embodiments, one load or constraint can be applied per object, although it may make sense to combine certain loads. Constraints can be honored regardless of applied forces.

In various embodiments, criteria can be used for a post-optimization check and may not affect the optimization process. Load cases can be described either in a global coordinate system (most common) or in a local shape coordinate system. Constraints can include, for example, prescribed displacement (displacements in the x, y, and z directions are specified), pinned joint (motion can occur “spinning” around an axis of a pin and/or along the pin), ball joint (motion can occur in all rotations around a ball joint center), planar slider (motion can occur within the specified plane, including in-plane rotation; out of plane motion and rotations are constrained), and linear slider (motion can occur in a single degree of freedom in one or more specified directions; all rotations can be constrained). Loads can include, for example, a simple force, a bearing force, a rigid body movement, acceleration, deceleration, pressure, and other criteria such as maximum displacement.

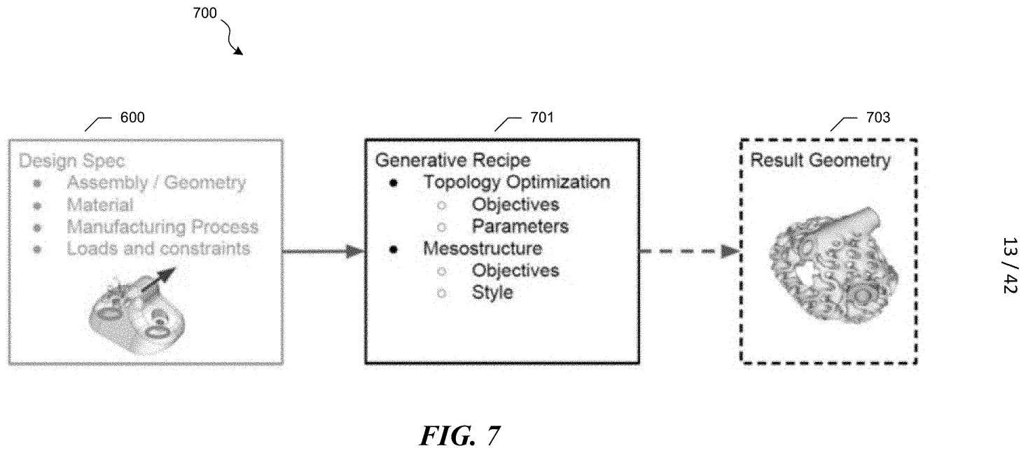

In various embodiments, density configurations of a density shape object can include information about any external interfaces that are not represented explicitly as other bodies in an assembly. These body-level external interfaces can be used to specify boundary conditions for an assembly. Density configurations can include, for example, keep-in, keep out, external interface, mask, and so on. Keep-in regions can be used for aesthetic reasons and/or to preserve features at sub-optimization resolutions. In several embodiments, when a keep-in region is specified, the system can apply loads and constraints throughout the shape volume. Keep-out regions can be used to specify a “soft” area where material is not to be present while preferring no sharp edges, such as over a precisely located surface. In various embodiments, when a keep-out region is specified, the system can apply loads and constraints to a shape's surface just outside a keep-out region. A mask region can be used to denote a shape's maximum extent. U.S. Pat. No. 10,042,817 describes various examples of density shape objects at, for example, FIGS. 7A-7G and their accompanying description.

External interface configurations can be used to specify one or more shapes, such as a part of an assembly, that are expected to interface with an optimized geometry. A design specification can include one or more assembly objects that include a set of bodies to indicate multiple objects to be simulated and/or optimized. A set of connection objects can also be present to indicate how these multiple bodies are connected. A connection object can reference two bodies in the set of bodies (e.g., by their index) and indicate how the bodies will interact.

Interactions, for example, can describe regions where the bodies are in contact with each other. Offsets and blending can be defined for objects A and B as if each was an external interface to the other. For example, an “offsetA” can add solid material to the body referenced by “bodylndexA” around any areas within a certain distance of body B, and “blendingA” can control the blending of the material into the rest of body A. U.S. Pat. No. 10,042,817 describes in detail methods used by the geometry kernel to blend intersecting bodies and generate optimized geometries for a set of design requirements.

In various embodiments, body-to-body connections can be handled at the assembly scope via connection objects. A body object can represent a single part, such as a continuous geometry made of a single material. A design specification file may contain a single set of body object keys at the root level to indicate a simple one part optimization. In one embodiment, a body can be an optimization body (if an optimality criteria object is present) or a scenery body. Scenery bodies can be assumed to be entirely full of density and may not change throughout the optimization process. Therefore, any filter stack can be ignored and keep in regions may have no effect other than as a means to apply external forces, if desired. Keep outs/external interfaces can modify the geometry even for scenery bodies. Scenery bodies can be simulated at each iteration and help form physical scenarios experienced by the optimization bodies.

In various embodiments, a body object can have an associated influence range. The influence range can be specified, for example, as a numeric distance from the boundary of the body object volume in all directions. The influence range can be used to define a magnitude of blending that occurs to the body object (e.g., in subsequent iterations). When two or more body objects are combined, the specified blending rules (e.g., the blending specification) can define whether the geometry blends together, and how the objects blend within overlapping regions of influence. For example, as described in U.S. Pat. No. 10,042,817 two surfaces that include one or more edges can be blended based on a falloff which can indicate how the surfaces transition to one another.

In various embodiments, each body objects combination can optionally have its influence range overridden to affect the magnitude of blending in subsequent combinations. For instance, two body objects may each have larger influences in order to blend together with a larger radius, then the influence can be overridden to a smaller value to do further operations with a different radius. This bottom up approach to blending is very different from the paradigm of applying BREP fillets/blends, but lies at the heart of the system's powerful procedural blending capabilities.

Simulation Framework

In accordance with one embodiment, a simulation framework 302 can be used for generative design of optimized geometries that necessitates a functional enhancement of finite element analysis (FEA) workflows. The simulation framework 302 can be used to inform design decisions as well as for analysis. In various embodiments, the simulation framework 302 can optimize the use of computing resources so that, for the received design requirements/specifications, a set of computations are performed to make well-informed design decisions in an efficient amount of time. In various embodiments, similar to the geometry kernel 301 that frees users to operate on a higher functional level of the assembly and not the minutiae of specifying an exact shape, the FEA workflows of the simulation framework 302 can operate on a higher functional level rather than user selection of points, edges, and surfaces.

The simulation framework 302 functionally can apply boundary conditions via the assembly structure. For example, in the BREP paradigm, the user may select a cylindrical surface of a hole and apply a force to it. This implies that there is something interacting with that surface, such as a shaft, that is exerting force on a simulated object. The simulation framework 302 can first model an envelope role, such as an outer boundary, of the shaft body object. The simulation framework 302 can then set-up an interaction between the surface body object and the envelope role of the shaft body object, where the interaction can control the desired geometric and/or physical interaction between the two body parts. The simulation framework can then directly apply boundary conditions, such as load(s) and/or constraint(s), to the shaft body part. In this manner, the system leads the user towards more realistic modeling of loading and/or constraint conditions by including surrounding load-transferring parts to simulate a part in its contextual assembly.

In various embodiments, the system can enable the user to easily modify different loads and/or constraints and efficiently generate optimized geometries corresponding to the modifications. For example, the user can easily switch a load-applying parameter from a geometric application of force to a true rigid body or even a simulated deformable body in order to more accurately apply loads, constraints, and/or boundary conditions.

Optimization Framework

A tradeoff encountered by the optimization framework 303 is an expected level of detail with respect to an amount of time needed to achieve a converged result. The system can enable a user to specify one or more of the following parameters that can be used by the optimization framework 303 to generate optimized geometries: minimum feature size, and minimum geometry thickness. These parameters help capture answers to the user's questions of “how fine detail can I expect to capture and generate in this optimization?”

In various embodiments, to maintain scale independence, a minimum feature size can be defined as a multiple of the elements (voxel) size. For example, idealMinimumFeatureThickVoxels (T) can be a top-level parameter of a recipe that defines this multiple. The value of the idealMinimumFeatureThickVoxels parameter can be used to capture the tradeoff between minimum feature size and element count. Element count is generally proportional to run time. If V is the volume of the design space and the user desires a minimum feature size of L, the approximate value of the maximum number of elements is equal to VT³/L³, where T is the value of the idealMinimumFeatureThickVoxels. This formula can be used in reverse to estimate minimum feature size per desired element count. For example, if T=3.5, on an optimization with element size of 0.5 mm, users should not expect features less than 1.75 mm thick to form. Likewise, the optimization framework 303 can warn if the users define keep-in regions that are thinner than ½ the minimum feature size. For T=3.5, that means any features that are less than approximately 2× elements thick (1.75×, to be exact) would throw a warning. This would be because anything less than this would have compromised structural results due to insufficient resolution. The degradation is fairly graceful, since sometimes features less than a single element thick will give good optimization results, but the user can be made aware of this.

In various embodiments, the optimization framework 303 can run in two modes: information gathering and optimization. The information gathering mode can be optional, but can provide useful values for an optimization setup dialog to present to a user. During the information gathering mode, the optimization framework 303 can gather values for one of more of the following parameters, for example, for the body objects in the assembly: design space volume, minimum volume fraction, maximum materials safety factor, and maximum modal frequency. The design space volume parameter can describe the approximate maximum volume of the body object if the design space were 100% filled. This can take into account subtracting keep out regions which may or may not be easily calculated by the calling app. The minimum volume fraction parameter can describe the minimum volume of the body object. For instance, keep-in regions can impose a floor on the amount of material that can be removed. This can be a percent or proportion (e.g. 0-1.0) of the design space volume that will always have material. The minimum volume fraction parameter can be used to enforce a lower bound on the desired volume a user can specify. The maximum materials safety factor parameter can describe a safety factor of the body simulated with 100% design space filled. No optimization can expect to exceed this maximum. The maximum modal frequency parameter can describe a fundamental natural frequency of the body object simulated with 100% design space filled. No optimization can expect to exceed this maximum. Table 1 depicts an example output snippet from the information gathering mode in accordance with one embodiment. This output reflects a design specification with three body objects, of which the last two are specified as optimization bodies with constrained volume fractions.

TABLE 1
idealMinimumFeatureThickVoxels, 4
designSpaceVolume(0), 344.98
designSpaceVolume(1), 530.15
minimumVolumeFraction(1), 0.091
designSpaceVolume(2), 182.1
minimumVolumeFraction(2), 0.224

The full optimization mode can perform the specified optimization. In the full optimization mode, the system can use the optimization framework 303 to perform generative design given a set of optimality criteria (e.g., received as optimization criteria/design requirements/specification) with the help of a recipe of design steps that can be applied sequentially.

Optimality Criteria

Optimality (optimization) criteria can inform or define goals of the optimization framework 303. If no optimality criteria is supplied for an object, the optimization framework 303 can consider the object as a scenery body. Optimality criteria can include, for example, one or more of: minimize (strain energy) subject to volume fraction, minimize (volume) subject to (material safety factor), minimize (Inverse minimum modal frequency) subject to (volume fraction), and minimize (strain energy) subject to (minimum modal frequency). When the minimize (strain energy) subject to (volume fraction) criteria is specified, the result of the optimization framework 303 will minimize strain energy for the specified volume fraction of the total available design space. When the minimize (volume) subject to (material safety factor) criteria is specified, the result will remove as much volume as possible without violating the specified material yield with factor of safety. When the minimize (Inverse minimum modal frequency) subject to (volume fraction) criteria is specified, the result will have the highest possible minimum normal mode frequency for the specified “percent full” of the total available design space. When the minimize (strain energy) subject to (minimum modal frequency) criteria is specified, the result will minimize strain energy while keeping all normal modes above the specified minimum frequency. Table 2 shows various example optimality criteria objects.

TABLE 2

| | |
|---|---|
| “optimalityCriteria”: { | “optimalityCriteria”: { |
| “minimize”: “strainEnergy”, | “minimize”: “volume”, |
| “constraint”: “volumeFraction”, | “constraint”: “materialSafetyFactor”, |
| “volumeFraction”: 0.75 | “materialSafetyFactor”: 2.0 |
| } | } |
| “optimalityCriteria”: { | “optimalityCriteria”: { |
| “minimize”: | “minimize”: “strainEnergy”, |
| “inverseMinModalFrequency”, | “constraint”: “minModalFrequency”, |
| “constraint”: “volumeFraction”, | “minModalFrequency”: 100 |
| “volumeFraction”: 0.75 | } |
| } | |

Table 3 shows examples of data elements of an optimality criteria object in accordance with one embodiment.

TABLE 3

| | | | | Default | | |
|---|---|---|---|---|---|---|
| Key | Type | Reqd? | Units | Value | Range | Notes |
| minimize | string | Y | n/a | n/a | | “strainEnergy”, |
| | | | | | | “volume”, or |
| | | | | | | “inverseMinModal- |
| | | | | | | Frequency” |
| constraint | string | Y | n/a | n/a | | “volumeFraction”, |
| | | | | | | “materialSafety- |
| | | | | | | Factor”, or |
| | | | | | | “minModalFrequency” |
| volumeFraction | number | N* | % | 1.0 | (0,1] | *required for |
| | | | | | | constraint of |
| | | | | | | volumeFraction. |
| materialSafety | number | N* | None | 1.0 | (0, ∞) | *required for |
| Factor | | | | | | constraint of |
| | | | | | | materialSafetyFactor. |
| minModal- | number | N* | Hz | 1.0 | (0, ∞) | *required for |
| Frequency | | | | | | constraint of |
| | | | | | | minModalFrequency. |

Design Recipe

The optimization framework 303 of the system 100 can process a design recipe or recipe file in order to perform an optimization. The design recipe can describe or specify how an optimization routine should go about achieving its goals. The design recipe can be used to specify a desired tradeoff between detail in the results and an amount of time it will take to complete the optimization. Recipes can be broken up into 1-N stages, which are generally used to guide an optimization along an efficient path. Each stage can include one or more steps. In various embodiments, earlier stages may be less strict and allow more exploration, whereas the later stages may be more strict in adhering to the optimization goals (optimality criteria).

Table 4 shows examples of stage parameters.

TABLE 4

| | | | | Default | | |
|---|---|---|---|---|---|---|
| Key | Type | Reqd? | Units | Val. | Range | Notes |
| method | string | Y | n/a | | | Design step to use |
| | | | | | | (optimize topology, |
| | | | | | | mesostructure, simulate, |
| | | | | | | parameter optimize, or |
| | | | | | | manufacturing |
| | | | | | | preparation) |
| label | string | N | | “” | | An optional (but highly |
| | | | | | | recommended) human |
| | | | | | | readable label indicating |
| | | | | | | the general purpose of this |
| | | | | | | stage |
| simElementType | string | N | | “hexahedral” | | Element type used for |
| | | | | | | simulate design step. |
| | | | | | | “hexahedral” is default. |
| | | | | | | Other values include |
| | | | | | | “timoshenko” |
| | | | | | | and “eulerBernoulli”. |
| maxSolver | number | N | None | 1/∞ | (0,1] | The maximum allowable |
| ResidualError | | | | | | relative residual error |
| | | | | | | remaining after the solve: |
| | | | | | | \|Ax-b\|/\|b\|. Larger values |
| | | | | | | will solve faster, but with |
| | | | | | | less accuracy. If the value |
| | | | | | | is too large the |
| | | | | | | homogenization will not |
| | | | | | | converge. To small will |
| | | | | | | take unnecessary time. |
| | | | | | | Typically 0.001 to 0.05. |
| maxDensityMove | number | N | None | 0.2 | (0,1] | Determines the maximum |
| | | | | | | amount of density (0 to 1 |
| | | | | | | scale) any location can |
| | | | | | | change in one iteration. |
| | | | | | | Large values can |
| | | | | | | overshoot and cause |
| | | | | | | longer solutions. Small |
| | | | | | | values may take |
| | | | | | | unnecessarily long to |
| | | | | | | follow direct optimization |
| | | | | | | paths. Typically 0.1-0.5. |
| penaltyFactor | number | N | None | 1.5 | [1,∞) | The “p” (penalization |
| | | | | | | factor) in optimize |
| | | | | | | topology design step of |
| | | | | | | the for x p where x is |
| | | | | | | density from 0 to 1. |
| | | | | | | Typically 1.0-3.0. 1.0 |
| | | | | | | represents no |
| | | | | | | penalization. Higher |
| | | | | | | penalization factors will |
| | | | | | | force density towards |
| | | | | | | either full or empty, |
| | | | | | | leaving less ambiguous |
| | | | | | | “middle ground”. |
| convergenceChange | number | N | None | 0.01 | (0,1] | Defines the threshold for |
| | | | | | | stage convergence. This |
| | | | | | | value is compared to the |
| | | | | | | maximum amount of |
| | | | | | | change of density (range 0 |
| | | | | | | to 1) at any location in the |
| | | | | | | structure during the last |
| | | | | | | step. if nothing has |
| | | | | | | changed more than this |
| | | | | | | value, stage is complete. |
| | | | | | | Typically 0.01 to 0.1 |
| minimumIterations | integer | N | count | 5 | (1-∞] | Minimum number of |
| | | | | | | iterations that must be |
| | | | | | | completed before a stage |
| | | | | | | can terminate. Avoids |
| | | | | | | premature convergence. |
| | | | | | | Typically 5-8. |
| maximumIterations | integer | N | count | 100 | (1-∞] | Upper limit of iterations to |
| | | | | | | cut off computation if a |
| | | | | | | stage will not converge. |
| | | | | | | Typically 50-500. |
| resolution | number | N | None | 0.01 | (0, ∞] | Multiples the resolution by |
| Multiplier | | | | | | this factor. Recommended |
| | | | | | | range is 1 to ~4.0. Time to |
| | | | | | | analyze will increase with |
| | | | | | | this value cubed. If “0.0” is |
| | | | | | | specified then the last |
| | | | | | | design step results will be |
| | | | | | | returned. |

A recipe including one or more steps and/or stages, with each stage including one or more design steps can be set up in a global designer. The term stage is used herein as a matter of convenience to refer to a single step or a grouping together of one or more steps, and as will be understood by one skilled in the art, the terms step and stage can generally be used interchangeably.

Any work to be done on one or more parts in an assembly can be specified in one or more part design steps registered for execution in one or more global design steps. In this manner, the optimization framework 303 can optimize parts either sequentially in isolation or simultaneously and interdependently.

In various embodiments, the results of one step or stage can be used as input for a next step or stage. In one regard, the output of a first design stage can be reviewed by a user in response to which the user can make adjustments to design requirements. The adjusted design requirements can be supplied along with the output of the first design stage as inputs to a second stage. By way of example, the output of the first design stage can be used to seed a subsequent or iterative generative design step or stage. In the case that the adjustments to the design requirements are minor, the output from the first design stage may be able to be reused or leveraged to improve computational efficiency by reusing prior computations or generative designs in part or whole.

In another regard, the output of a first design step or stage can be used as a requirement of or as part of the design requirements for a second step or stage. An example recipe might include a first stage including an optimize topology design step that creates a three dimensional geometry, which is then followed by a mesostructured design step that takes the three dimensional geometry as an input or requirement and applies a mesostructure to the interior of the geometry using generative design. Input, such as user input, can be optionally requested and received between the two design steps. A second stage can include a manufacturing preparation design step based on the output of the first stage.

In various embodiments, a design stage can include design steps arranged in a tree structure arrangement. For example, a design stage can include an optimize topology step followed by two manufacturing preparation steps: (1) additive and (2) machining blueprints. The two manufacturing preparation steps can be executed sequentially and/or in parallel. A design recipe can also be configured such that a design step or stage must be completed before the next step or stage is considered by the optimization framework 303.

Design steps can be classified, for example, as: optimize topology, mesostructure, simulate, parameter optimize, and manufacturing preparation, each of which will be discussed below.

Optimize Topology

Optimize topology design steps can be included to optimize material distribution (or three dimensional geometry) according to a user specified set of objectives and/or filters. As discussed above, there can be a tradeoff between the required amount of detail and the amount of time needed to optimize at certain level of detail. That tradeoff can be specified through a user defined “minimum feature size.” This value indicates the smallest size of feature that is expected in a design. The smaller the minimum feature size, the longer the optimization will generally take to complete.

In addition to objectives, a set of filters can be applied to modify a resulting geometry. Simple filters like symmetry (planar or rotational) can enforce shape symmetry regardless of the asymmetric loading conditions found in the real world. Other filters (e.g., extrude bidirectional, extrude unidirectional, draft, void fill, material spreading, and self-supporting) can enable shapes suitable for manufacturing with multiple (e.g., two or three) axis machining, casting/molding, or efficient additive manufacturing. By choosing and arranging geometric filters appropriately, a wide variety of objectives can be attained.

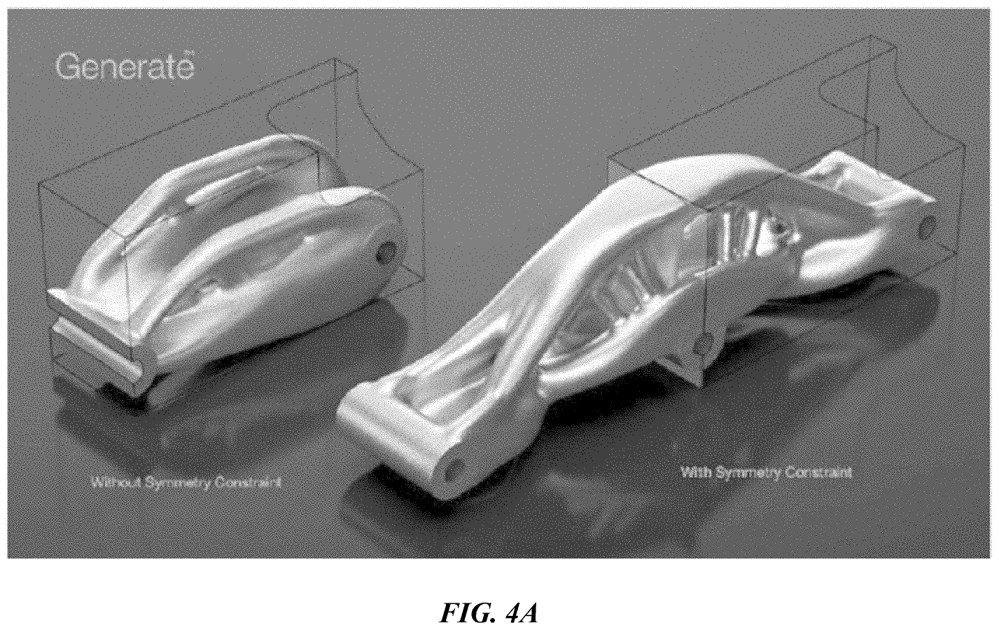

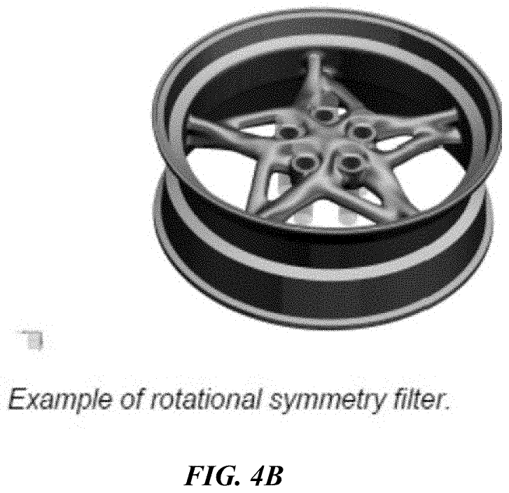

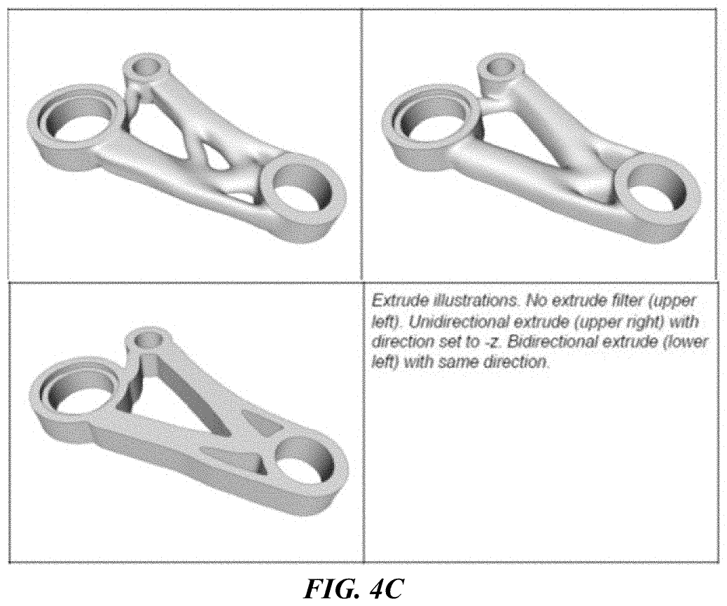

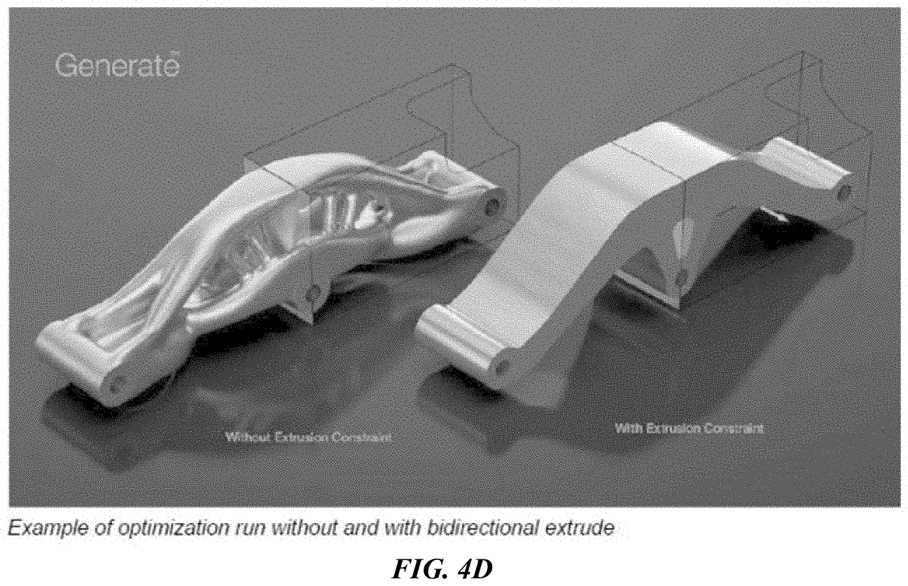

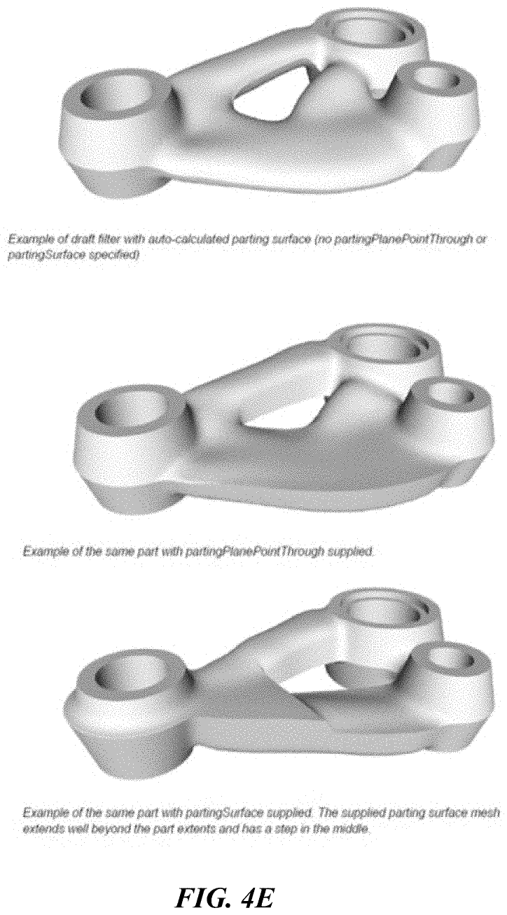

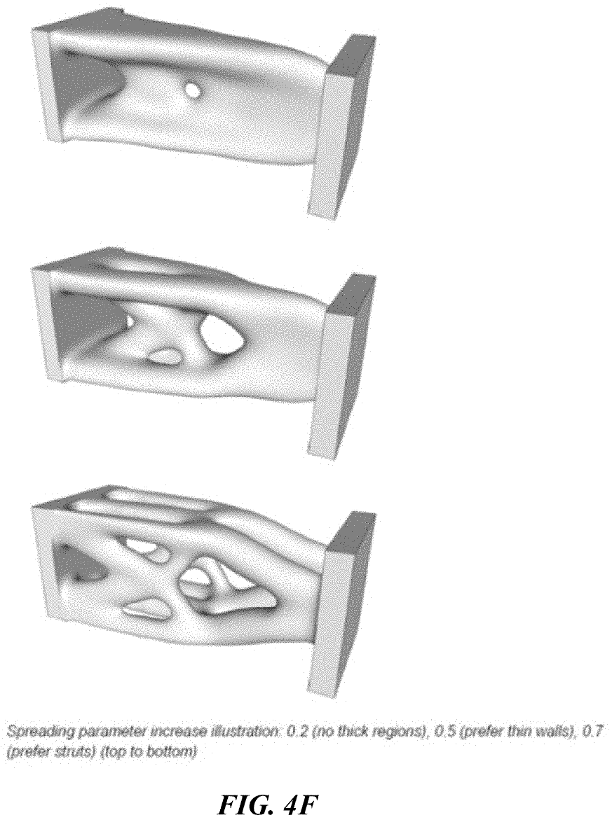

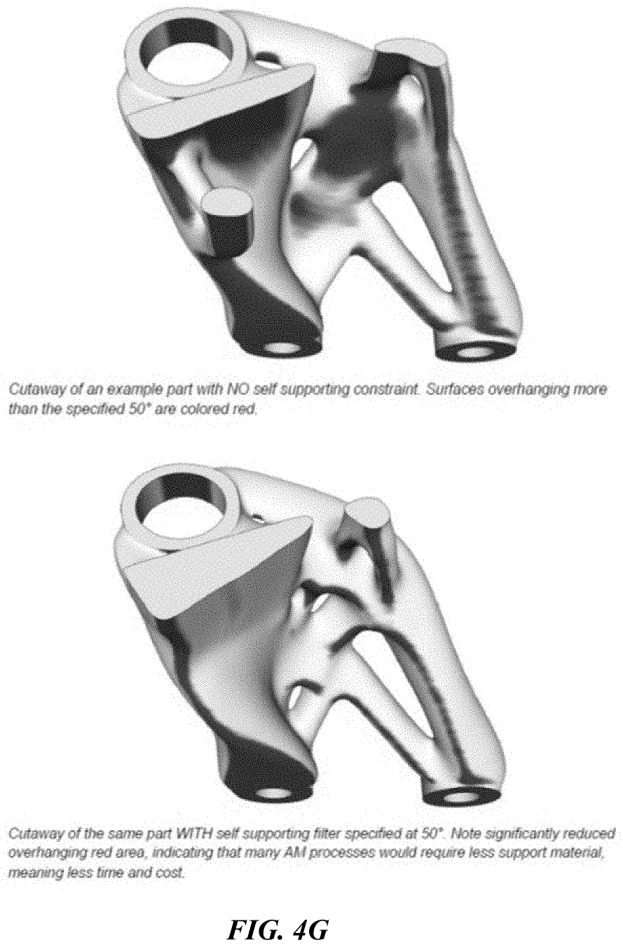

FIG. 4A illustrates examples of results from the optimization framework run with and without a planar symmetry filter. A planar symmetry filter can be used to create planar symmetric shapes where the optimized density is symmetric about a specified plane.

FIG. 4B illustrates an example of a rotational symmetry filter and its application to generate an optimized geometry. A rotational symmetry filter can be used to create rotationally symmetric shapes where the optimized density is rotationally symmetric about a specified axis at a given number of evenly spaced instances.

FIGS. 4C-4D illustrate examples of results from the optimization framework run with and without extrude filters. Extrude filters (bidirectional/unidirectional) can be used to generate an optimized geometry that is linearly extruded and that may sharply intersect the design space at the boundaries it hits.

FIG. 4E illustrates examples of results from the optimization framework run with different draft filters. A draft filter is suitable for molding/casting where the optimized geometries are not allowed to create any overhangs less than a given draft angle in a specified draw direction. For example, the draft filter can be used on parts to be cast or molded with a given pull direction. A neutral plane or surface may optionally be defined as the parting surface of the intended mold so that no overhangs from this surface violate the draft angle. A neutral surface can unambiguously span the entire design space and can have no angles less than the draft angle relative to the draw direction. If no neutral surface is specified, the most optimal neutral surface can be calculated and used. A draft void filling filter can be used to generate optimized geometries that do not comprise fully enclosed voids.

FIG. 4F illustrates examples of results from the optimization framework run with different material spreading filters. A material spreading filter can be used to control preferences towards solids with voids, walls, thin members, and so on by controlling how spread out the material should be. For example, a spreading value of 0.0 will have no effect, while a spreading value around 0.2 will begin to hollow out thick solid regions, potentially creating voids. A spreading value around 0.4 will tend towards thin-walled structures and a spreading value around 0.7 can indicate a practical upper limit that will push the material to spread into only struts.

FIG. 4G illustrates example of results from the optimization framework run with a self-supporting filter. A self-supporting filter can be used as an additive manufacturing buildability filter to reduce or eliminate the need for support material during the build process.

Mesostructure

A mesostructure design step can modify a part by filling specified generative regions with some sort of higher complexity infill. In various embodiments, this infill can be optimized algorithmically. In certain embodiments, a pattern may be specified by the user (e.g., received as part of the design recipe), such as a desired size of honeycomb infill. In various embodiments, parameters of the infill can be mapped to scalar fields in order to spatially vary the properties of the mesostructure. For instance, a stress result scalar field can be selected from a previous simulation step to thicken the lattice in high stress regions in a subsequent step or stage. A user-defined expression in x, y, and z can be used to control cell size. Altogether, this creates a powerful tool for functionally aware light weighting parts.

In various embodiments, a design recipe can include information about one or more mesostructures and/or lattices used to generate an optimized geometry. For example, the thickness or sizing of a mesostructure can spatially vary according to the functional requirements of an object.

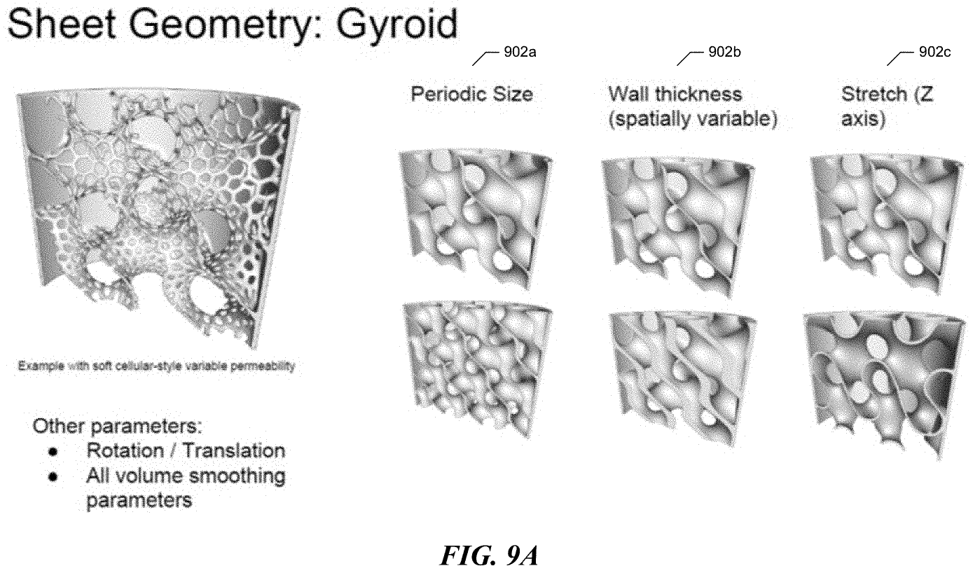

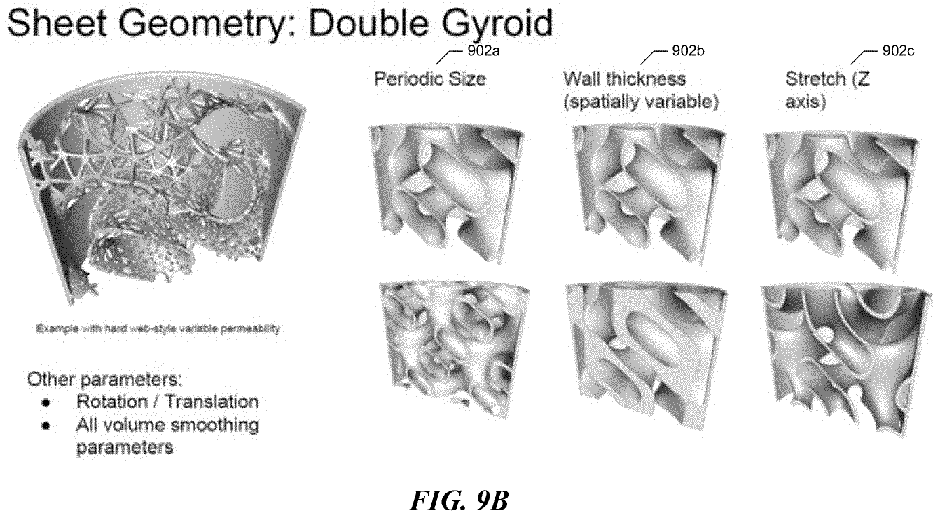

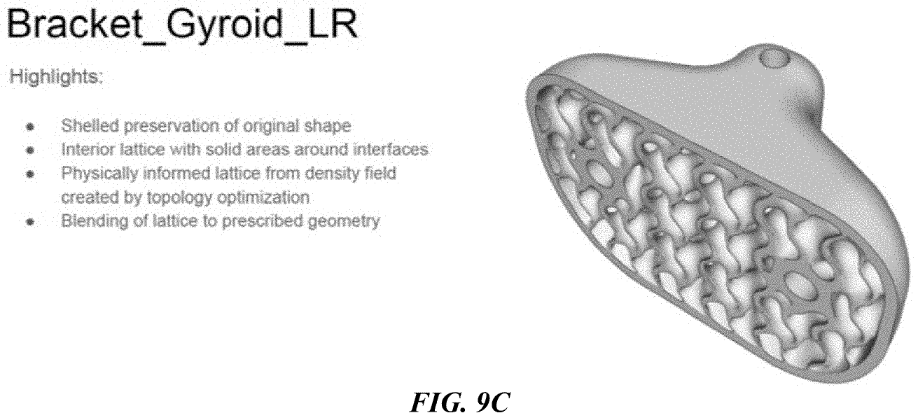

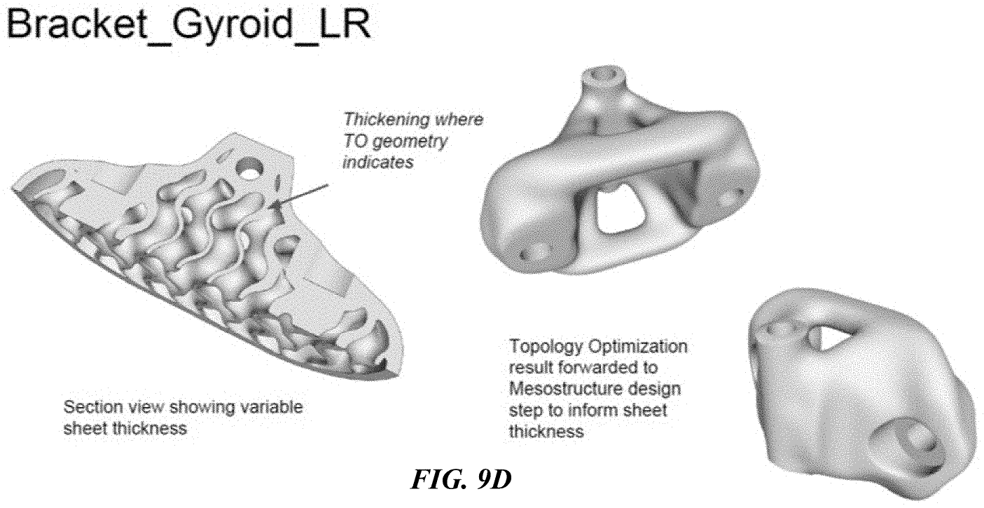

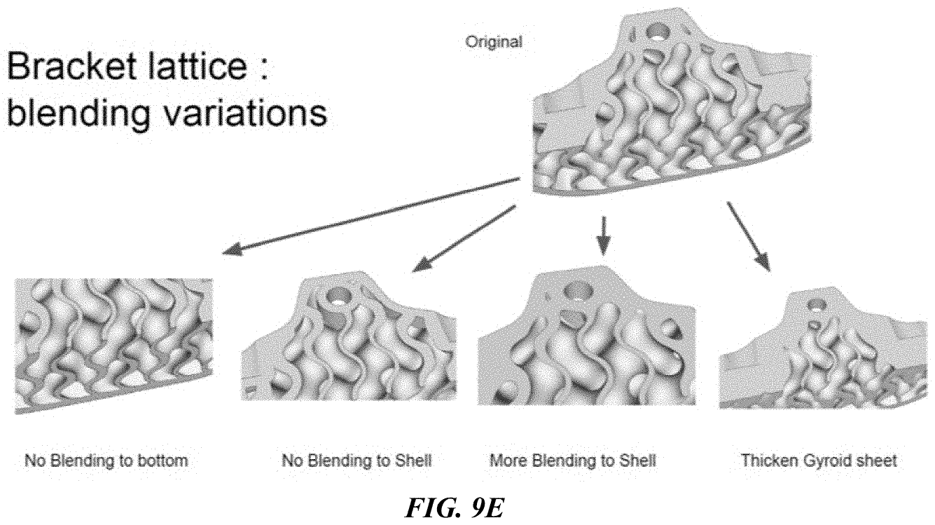

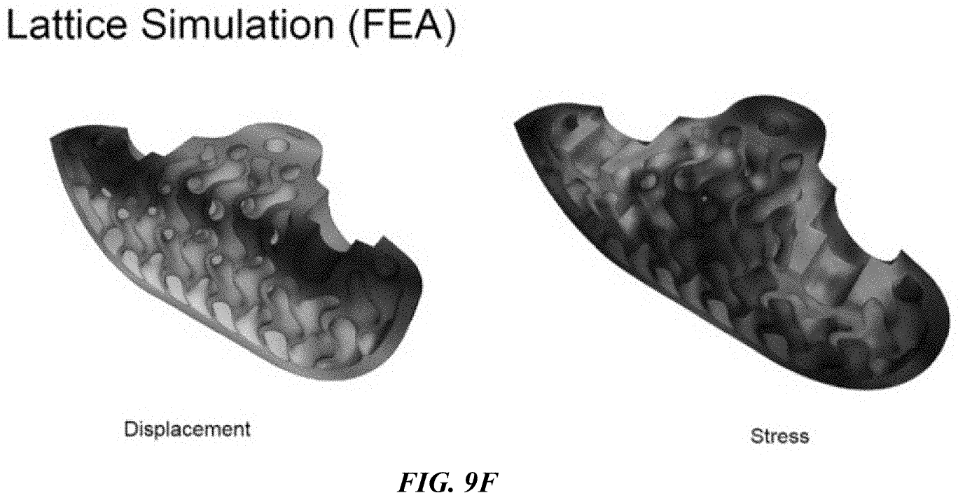

FIGS. 9A-9F illustrate examples of gyroid-based mesostructures/lattices and a bracket shaped body object generated using the gyroid-based mesostructures/lattices. FIGS. 9A-9B illustrate examples of gyroid-based and double gyroid-based mesostructures respectively having different parameters (e.g., periodic size 902a, wall thickness 902b, and stretch 902c). Such parameters can include, for example, rotation/translation and smoothing. FIGS. 9C-9E illustrate an example bracket shaped body object generated using the gyroid-based mesostructure/lattice with different parameter values. FIG. 9F illustrates an example of executing a simulate design step (discussed below) on the bracket shaped body object generated using the gyroid-based mesostructure/lattice.

FIG. 9D illustrates an example where three dimensional geometry results from a topology optimization step are used as input criteria or requirements to create a new geometry in a subsequent mesostructure design step. The mesostructure design step takes the three dimensional geometry and applies a mesostructure within the interior of the geometry to produce a final geometry.

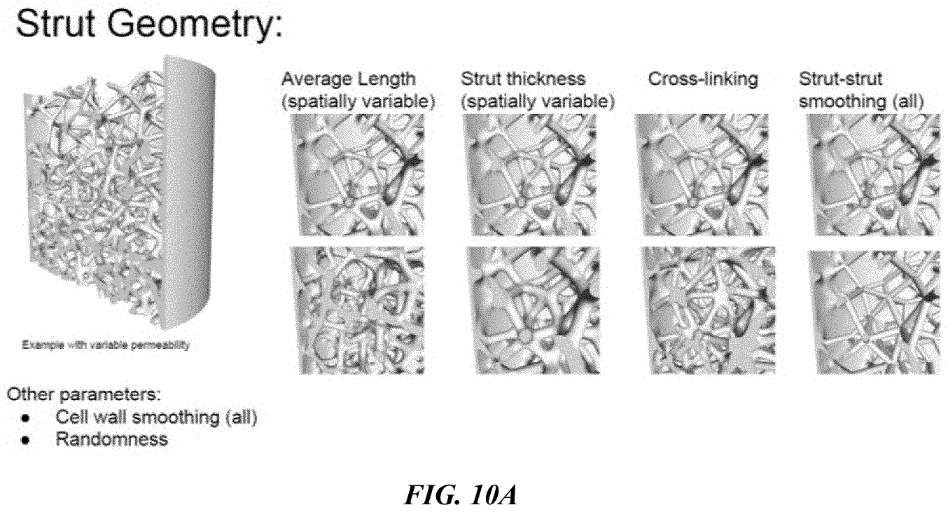

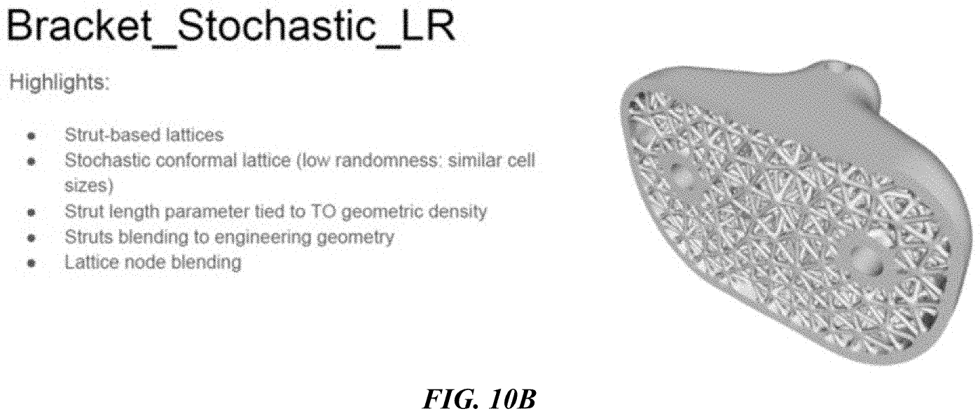

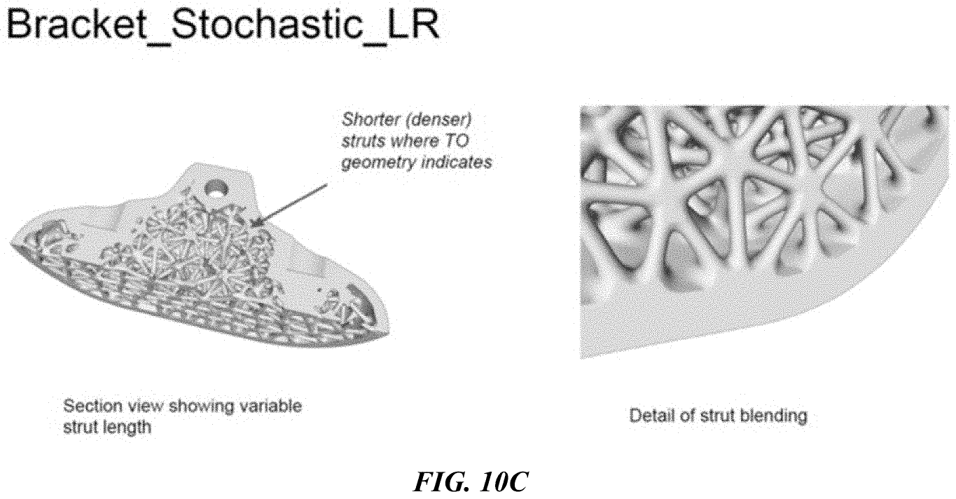

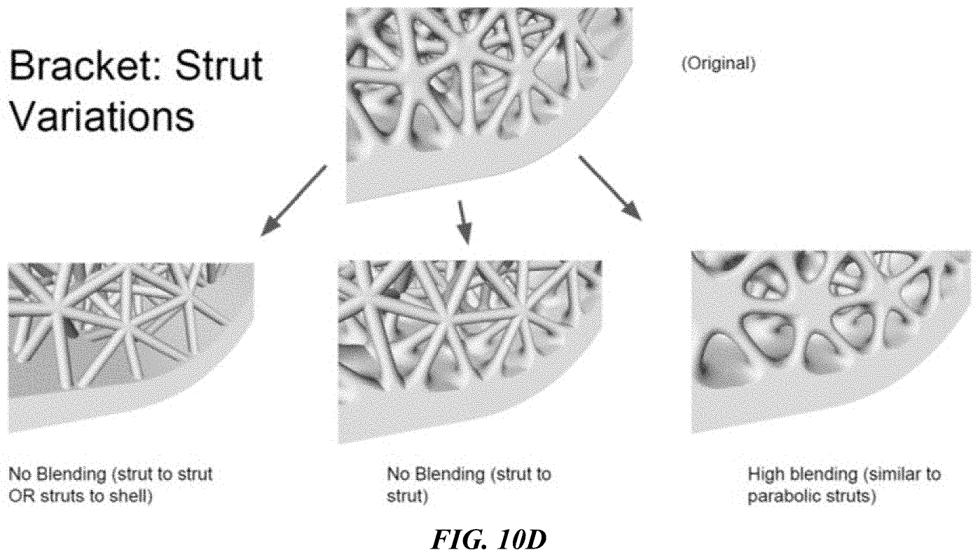

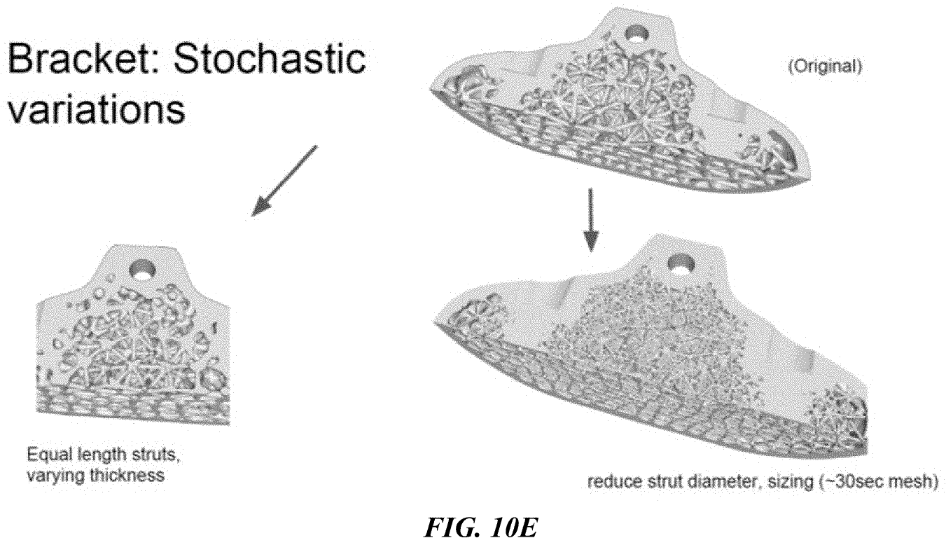

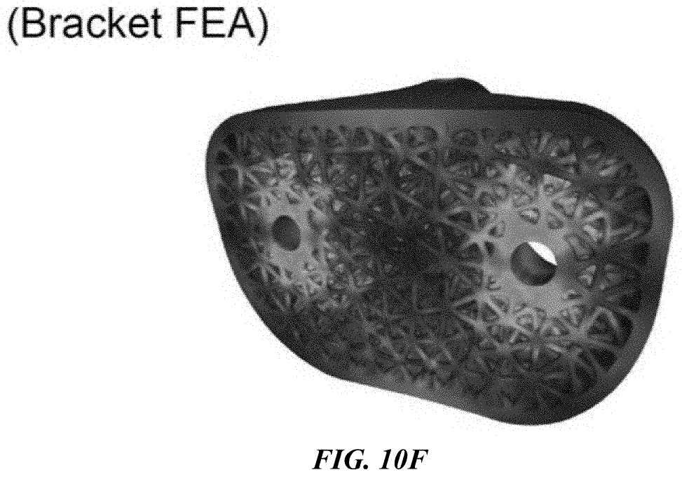

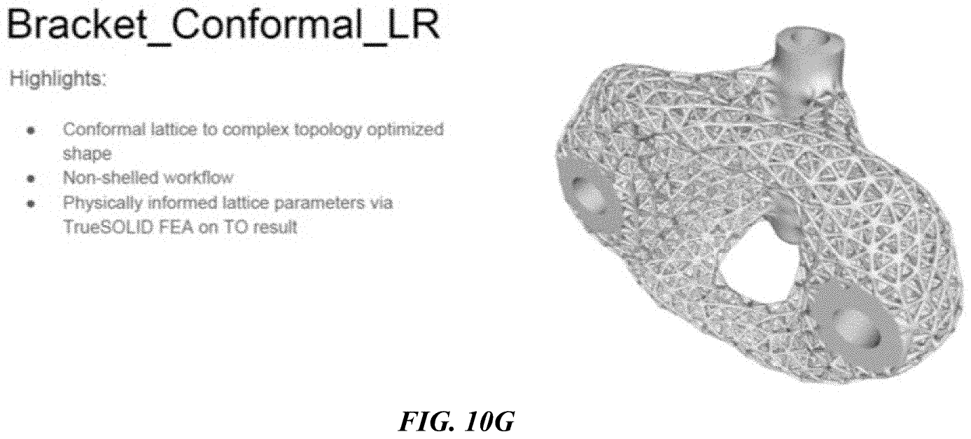

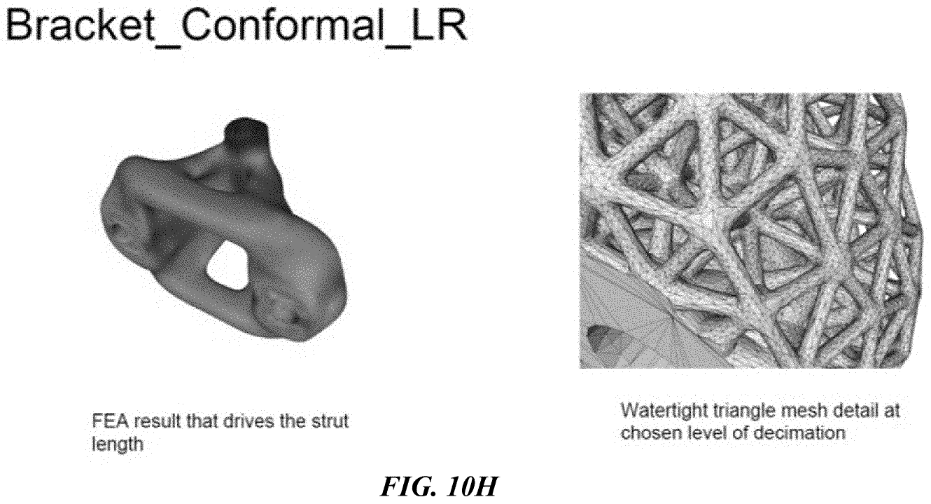

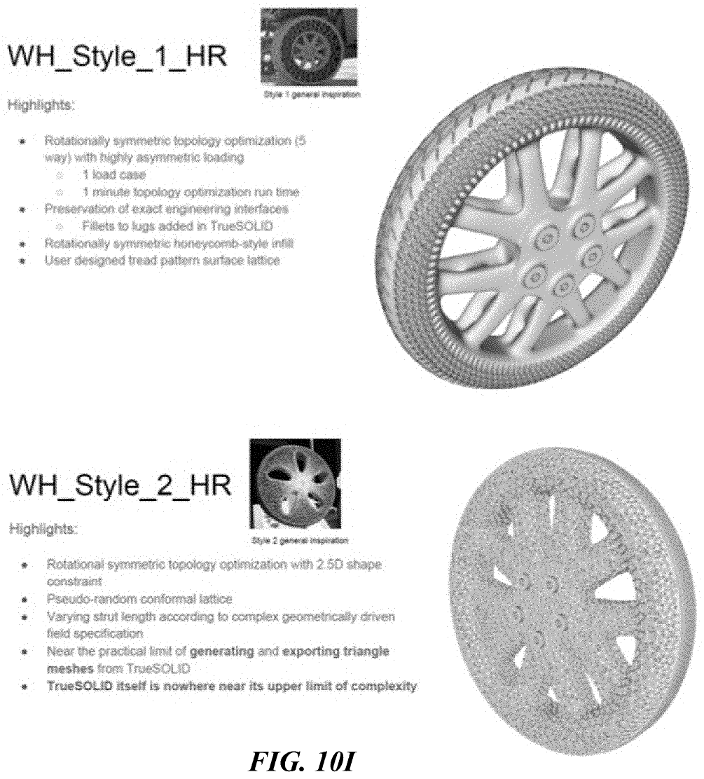

FIGS. 10A-9F illustrate examples of strut-based mesostructures and strut-based lattices. FIG. 10A illustrates examples of a strut-based mesostructures having different parameters (for example, average length 1002a, strut thickness 1002b, cross-linking 1002c, and strut-strut smoothing 1002d). Other examples of parameters include, but are not limited to cell wall smoothing, randomness, and so on. FIGS. 10B-10E illustrate example bracket shaped body object generated using the strut-based mesostructure/lattice with different parameter values. FIG. 10F illustrates an example of executing a simulate design step (discussed below) on the bracket shaped body object generated using the strut-based mesostructure/lattice.

In certain embodiments, a user can specify that one or more mesostructures/lattices to be applied to a body object conform to the body object. FIG. 10G illustrates an example of conforming a strut lattice to the shape of a bracket body object. This ensures that there are no (or minimal) sharp edges when the lattice is applied to the body object. FIG. 10H illustrates an example of executing a simulate design step (discussed below) and an instantiation framework step (discussed below) on the bracket shaped body object generated using the conforming strut-based mesostructure/lattice. FIG. 101 illustrates an example wheel shaped body object generated using rotational symmetric topology optimization and the strut-based mesostructure/lattice with different parameter values.

In various embodiments, the system can provide recommended recipes based on desired time or detail levels. Within a stage, one or more parameters can be adjusted with direct effect on time and accuracy of the optimization routine.

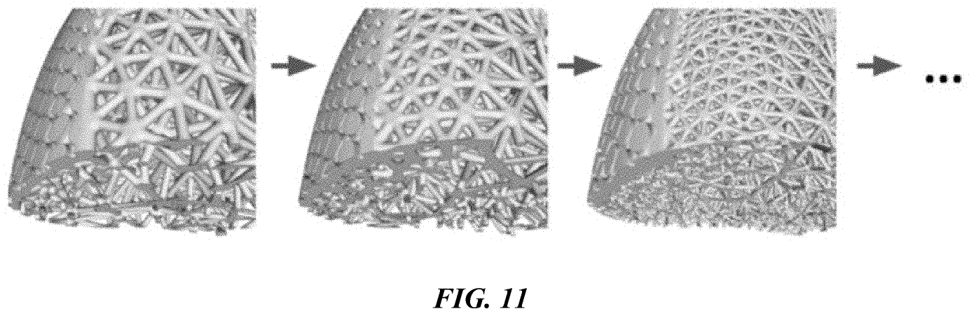

FIG. 11 illustrates example outputs from the optimization framework 303 for different optimization criteria and/or design requirements. For example, in subsequent iterations of an optimization, the user can increase resolution, which may result in a longer computation time to reach a result. The results of the prior iterations using lower resolutions, however, can be leveraged in order to avoid save additional computations and decrease the time to produce the subsequent results.

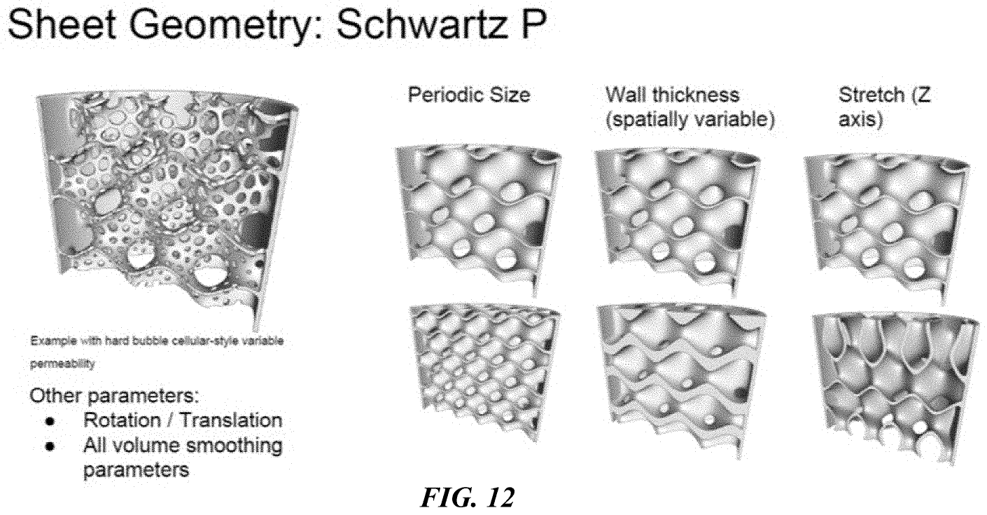

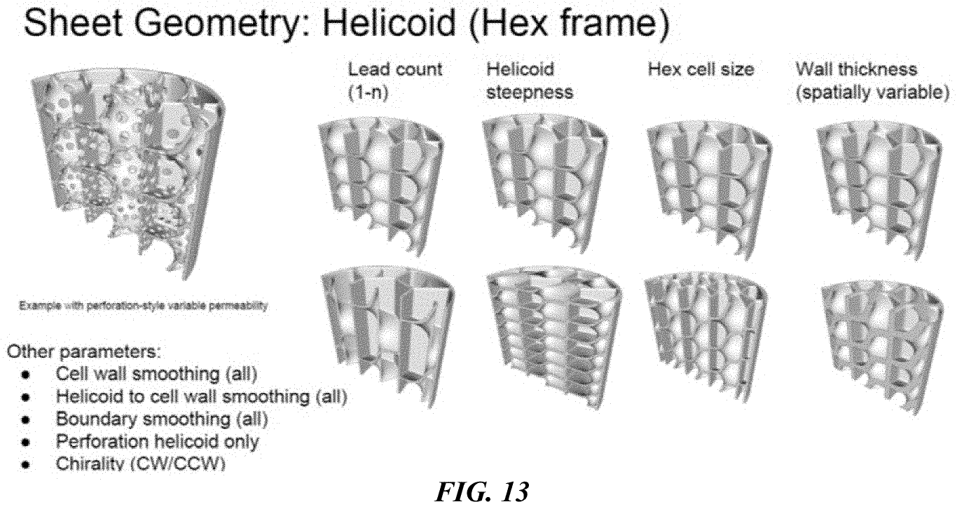

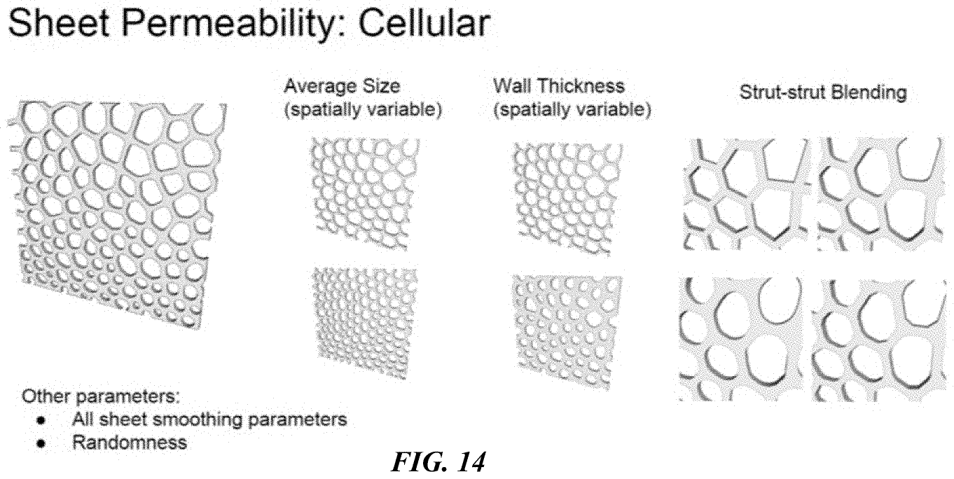

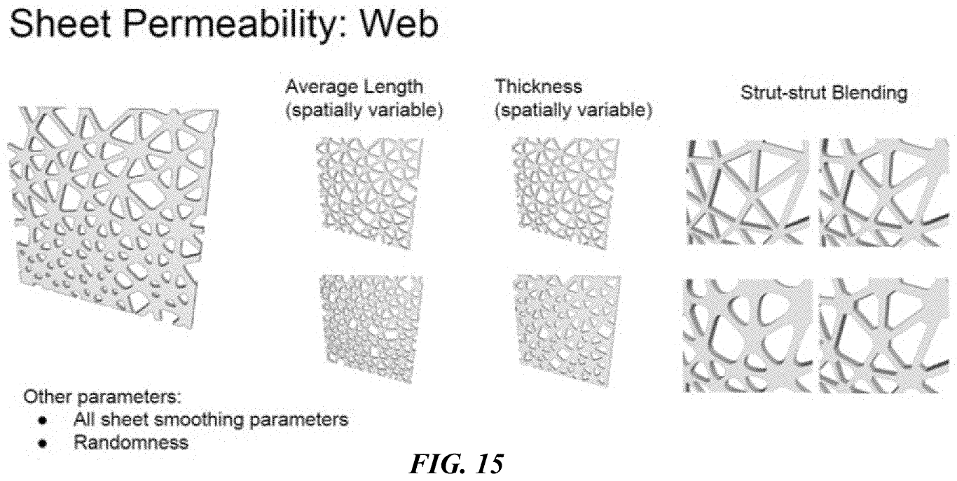

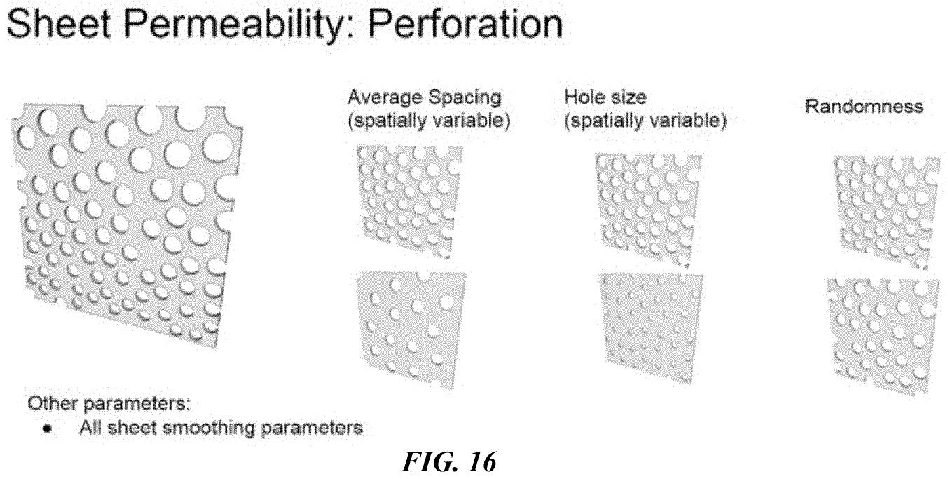

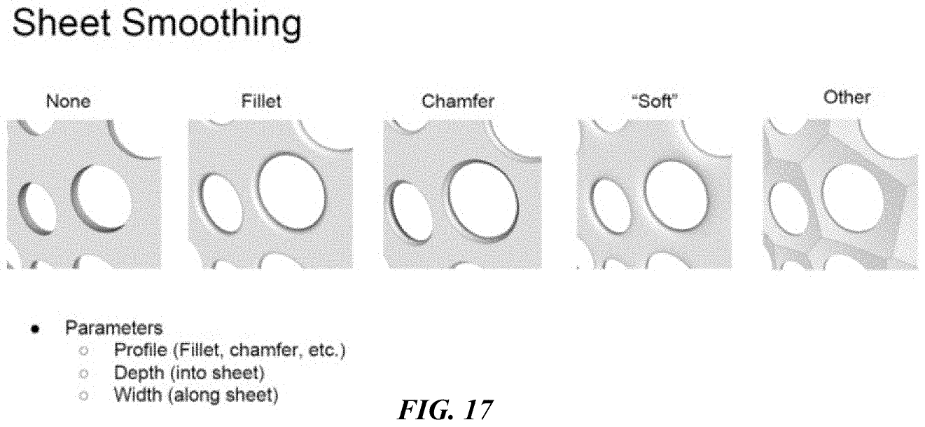

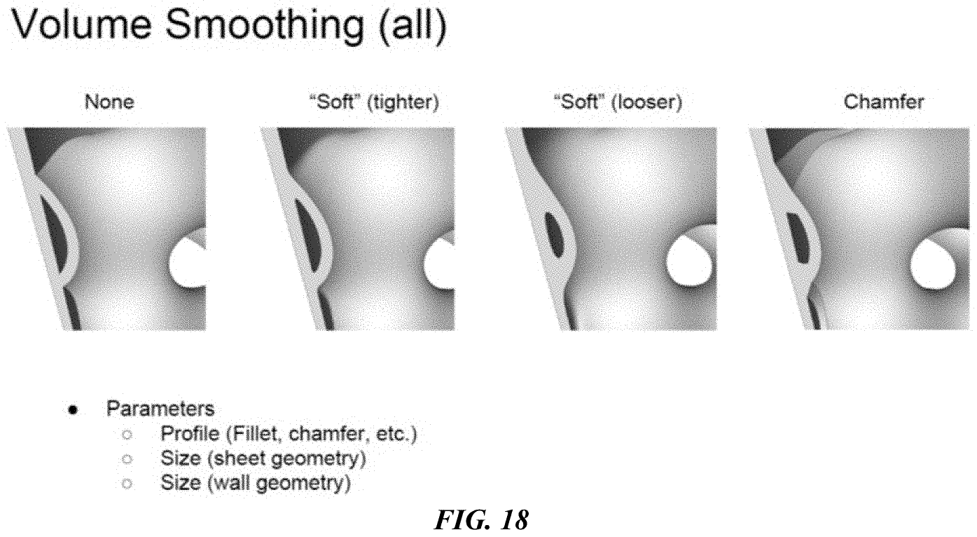

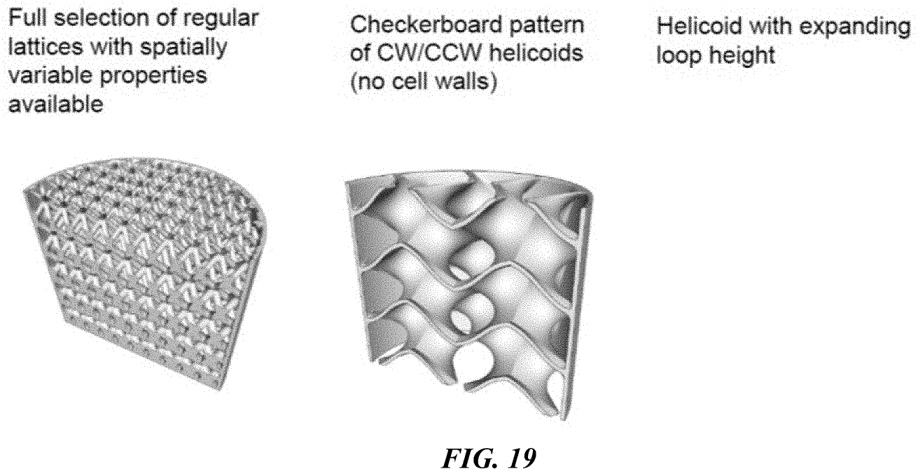

FIGS. 12-19 illustrate examples of other types of mesostructures/lattices.

Simulate

A simulate design step provides simulation results at user-specified settings and need not change the geometry of a design. The simulate step can be used with appropriate settings whenever showing finite element analysis (FEA) results to a user that may be used for quantitative analysis on the performance of a part. The simulation can be made fast enough to provide a real time experience of FEA results updating while design changes are being made.

Parameter Optimize

Parameter optimize design steps can support multi-effective optimization to determine optimal inputs to later design steps/stages. For example, a parameter optimize design step can be used to identify an optimized orientation of a part for a manufacturing preparation (additive) step. This can be done, for example, because sometimes it may be better, based on a part shape, to manufacture the part upside down.

Manufacturing Preparation

Manufacturing preparation design steps can be used to prepare an optimized geometry for manufacturing. Examples include additive steps to add extra material to an additive print that can then be removed during post-processing after the part is manufactured (e.g., machine-off or post machine (relevant for additive/casting)). As another example, an additive step can add materials to an optimized geometry for a smooth surface which is not part of the optimized geometry but can be manufactured first and then sawed off later after manufacturing. Another example can be adding support structures that are not part of an optimized geometry but that may be necessary for the manufacture of a design using additive manufacturing techniques. These structures can then be removed and discarded after the optimized geometry is manufactured.

Instantiation Framework

In various embodiments, the results of the optimization framework 303 can be sent to a instantiation framework 304. The instantiation framework 304 can take the results of the optimizer framework 303 and generate a visualization/blueprint of the optimized geometry. The visualization/blueprint makes the geometry tangible for manufacturing, for example, using one or more manufacturing methods discussed above. Examples of blueprints can include meshes, slices, and tool paths.

The instantiation framework 304, for example, can fit a triangle mesh to the surfaces of the optimized geometry generated by the optimization framework 303. The mesh can be output in different formats (such as stl, x3d, or jt formats). In various embodiments, the mesh can be colored according to one or more color keys to show physical simulation results. In various embodiments, the mesh can be decimated.

Decimation can be specified by a maximum triangle count (decimatemaxtriangles) and/or a threshold factor (decimatethreshhold).

Table 5 provides examples of the threshold factor.

TABLE 5

| Decimation level | Value | Comments |
|---|---|---|
| Very Low | 0.1 | Almost no triangles removed, |
| | | shape well preserved |
| Low | 0.033 | |
| Medium | 0.01 | |
| High | 0.0033 | |
| Very High | 0.001 | Majority of triangles removed, |
| | | shape may be rough |

In various embodiments, the normals of the triangle mesh can be calculated and stored. Any edges above a specified angle (e.g. in degrees) can be rendered as sharp while all others can be rendered as smooth.

General Processes

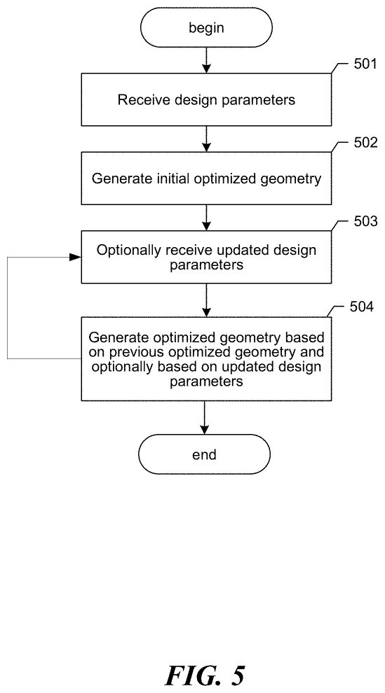

FIG. 5 is a flow diagram showing a process for generating optimized geometries by the system 100.

At act 501, the system receives design requirements/parameters and/or a design recipe.

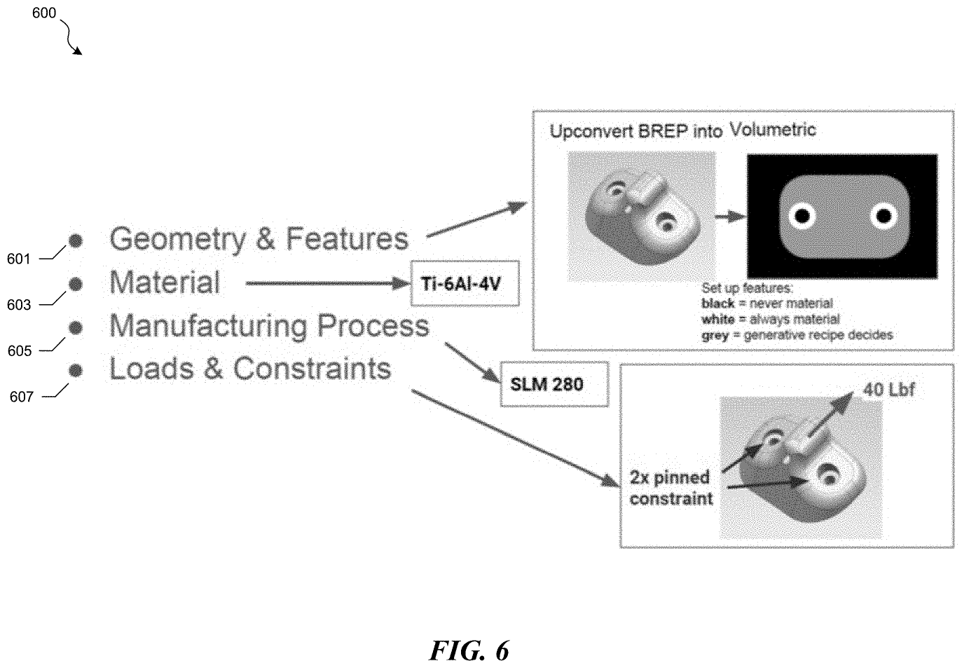

FIG. 6 illustrates, for example, that the system can receive information related to the geometry and features 601, material 603, manufacturing process 605, and loads and constraints 607.

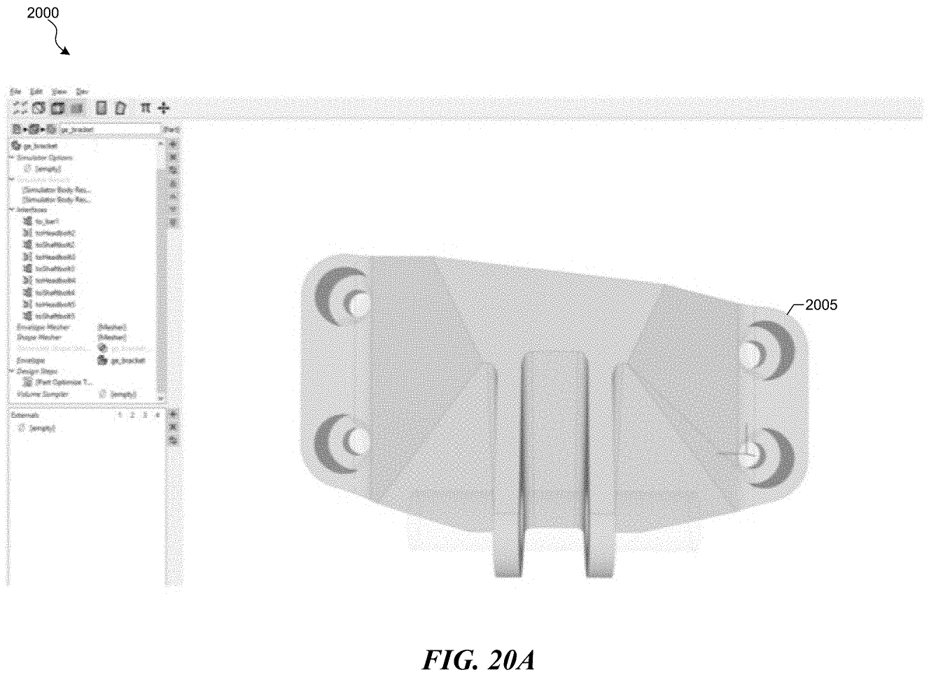

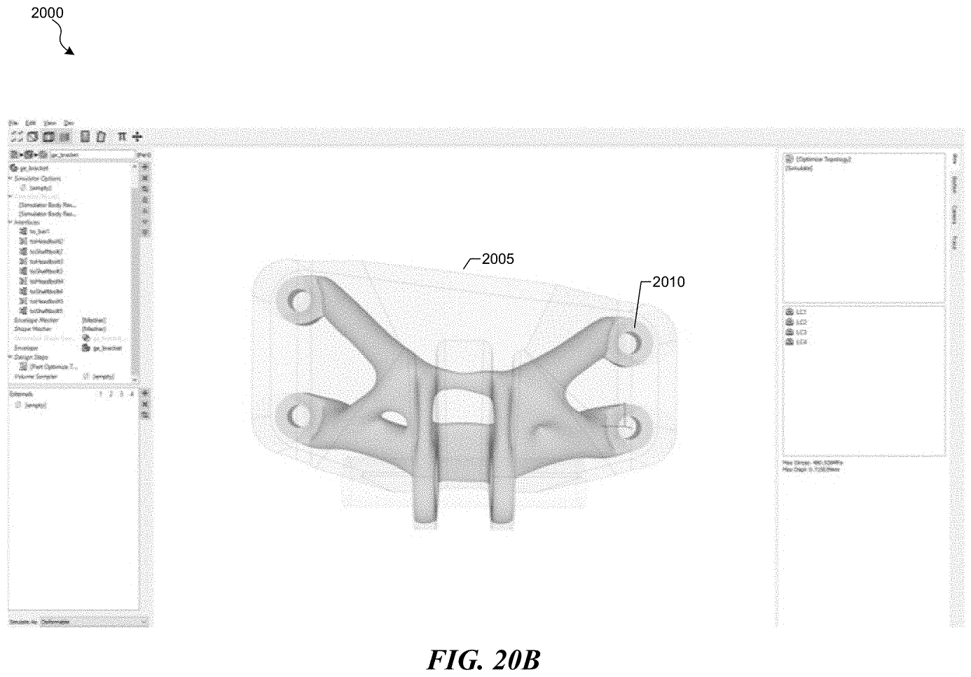

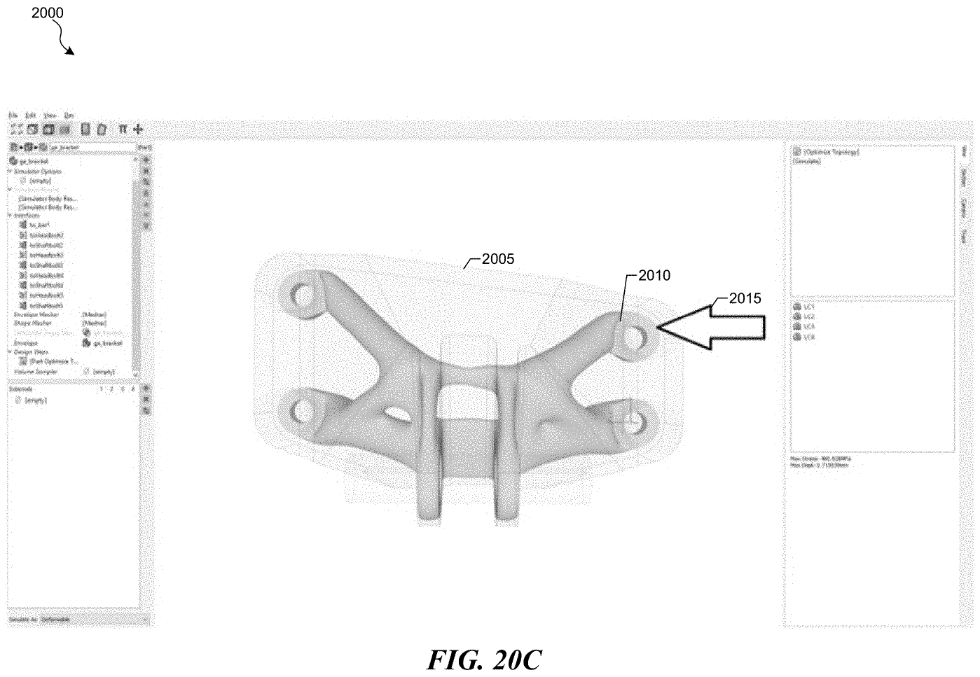

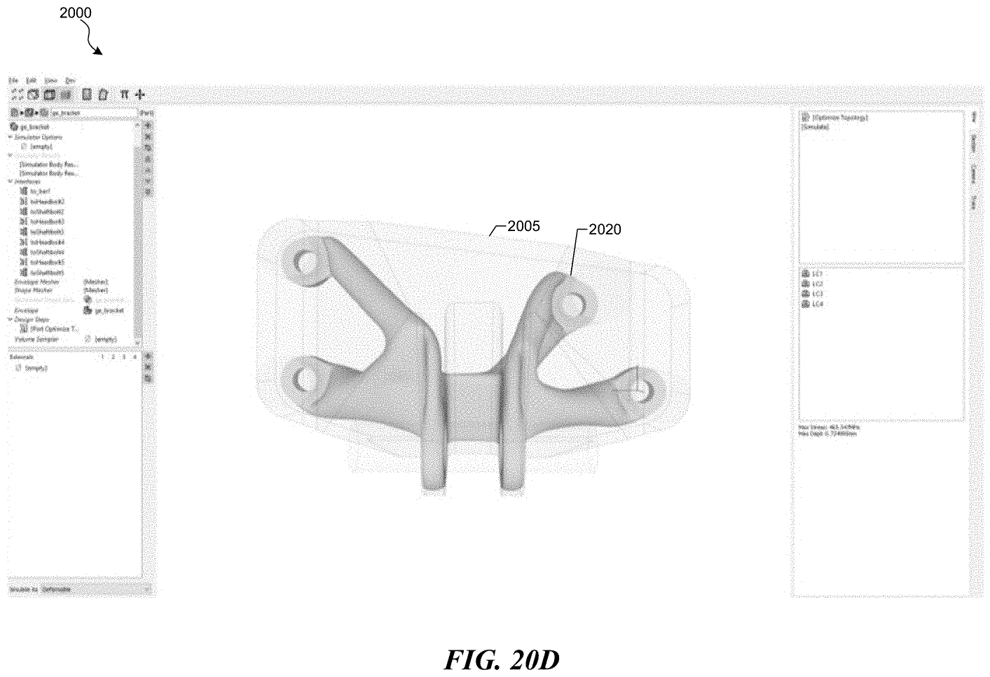

FIG. 20A illustrates an example user interface 2000 for receiving design requirements for an object 2005.

At an act 502, the system can process the received information to generate an initial optimized geometry. As illustrated in FIG. 7, for example, the system can generate an initial optimized geometry 703 based on the received design requirements/parameters 600 and/or a generative design recipe 701.

FIG. 20B illustrates an example user interface 2000 that shows an optimized geometry 2010 generated based on received design requirements for an object 2005.

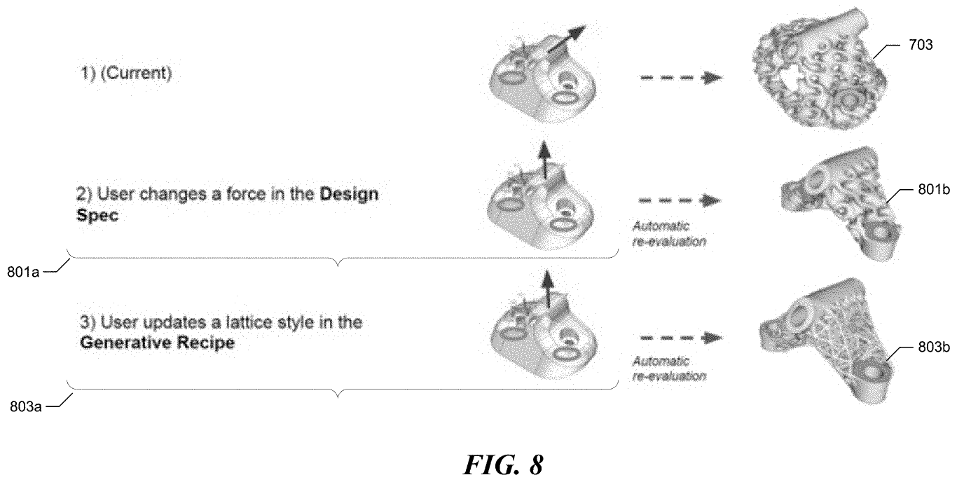

At act 503, the system can optionally receive updates to one or more design requirements/parameters and/or a design recipe used to generate the initial optimized geometry. As illustrated in FIG. 8, for example, the system can receive updated load case parameters (direction of a force, 801a) and/or updated recipe parameters (lattice style in the generative recipe, 803a).

FIG. 20C illustrates an example user interface 2000 that receives an updated load case parameter of a force 2015 in the direction of the illustrated arrow on the upper-right bolt of the geometry of FIG. 20B.

At an act 504, the system generates an optimized geometry based on the previous optimized geometry. In one aspect, the geometry can be an updated generated in response to and corresponding to updated parameters received in act 503. As illustrated in FIG. 8, for example, upon receiving the updated design parameters 801a, the system can derive a corresponding updated optimized geometry 801b using the initial geometry generated using the initial design parameters 703.

FIG. 20D illustrates an example user interface 2000 that shows an optimized geometry 2020 based on the updated force parameter 2015 and the previously generated geometry 2010.

The system can perform acts 503 and 504 iteratively as it receives updated design requirements/parameters and/or an updated generative design recipe. Referring again toe FIG. 8, when a user makes another change 803a to the design recipe, the system derives the corresponding updated geometry 803b using the previously generated geometry 801b. Referring to FIG. 11, for example, a user can supply two updates to design requirements and/or parameters to iterate two times from the structure on the left, then to the structure in the center and finally to the structure on the right. By using the previous optimized geometry, additional computation work can be avoided and the iterations can be produced more efficiently.

In various embodiments, the system enables a user to specify a previously generated optimized geometry version which is used to derive an updated geometry. For example, the system can enable the user to select either previously generated geometry 703 or previously generated geometry 801b as the starting point for deriving the updated optimized geometry 803b.

In another aspect, at the act 504, the optimized geometry can be a new geometry created by using the previous optimized geometry as an input or starting point, in conjunction with optimization criteria already or otherwise specified in a design recipe for generating the new optimized geometry. In this aspect, the previous optimized geometry can be used as a requirement and/or as one or more of the criteria in a subsequent design stage, optionally without requiring further user input between the two stages.

FIG. 9D illustrates an example where three dimensional geometry results from a topology optimization step are used as input criteria or requirements to create a new geometry in a subsequent mesostructure design step. The mesostructure design step takes the three dimensional geometry and applies a mesostructure within the interior of the geometry to produce a final geometry.

Conclusion

The above embodiments of the invention are not intended to be exhaustive or to limit the invention to the precise form disclosed above. While specific examples for the invention are described above for illustrative purposes, various equivalent modifications are possible within the scope of the invention, as those skilled in the relevant art will recognize. For example, while processes or acts or blocks may be presented in a given order, alternative implementations can perform routines having acts, or employ systems having blocks, in a different order, and some processes or acts or blocks can be deleted, moved, added, subdivided, combined, and/or modified to provide alternative or subcombinations. Each of these processes or acts or blocks can be implemented in a variety of different ways. Also, while processes or acts or blocks are at times shown as being performed in series, these processes or acts or blocks can instead be performed or implemented in parallel, or can be performed at different times. Further any specific numbers noted herein are only examples: alternative implementations can employ differing values or ranges.

The teachings provided herein can be applied to other systems, not necessarily the system described above. The elements and acts of the various examples described above can be combined to provide further implementations of the invention. Some alternative implementations of the invention can include not only additional elements to those implementations noted above, but also can include fewer elements.

Aspects of the invention can be modified, if necessary, to employ the systems, functions, and concepts of the various references described above to provide yet further implementations of the invention. When statements or subject matter in an incorporated by reference conflict with statements or subject matter of this application, then this application shall control.

These and other changes can be made to the invention in light of the above description. While the above description describes certain examples of the invention, and describes the best mode contemplated, no matter how detailed the above appears in text, the invention can be practiced in many ways. Details of the system can vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

In the claims, the term “based upon” shall include situations in which a factor is taken into account directly and/or indirectly, and possibly in conjunction with other factors, in producing a result or effect. In the claims, a portion shall include greater than none and up to the whole of a thing. In method claims, any reference characters are used for convenience of description only, and do not indicate a particular order for performing a method.

1. A method performed by a computing system having at least one processor and a memory, the method comprising:
receiving a first set of user-supplied design requirements for a computer aided design geometry;
executing a first generative design process to generate a first optimized geometry based on the first set of user-supplied design requirements; and
executing a second generative design process to generate a second optimized geometry based on a second set of user-supplied design requirements for the computer aided design geometry and based on applying the first optimized geometry as a requirement for the second optimized geometry.

2. The method of claim 1, further comprising:
in response to presenting the first optimized geometry in a computer user interface, receiving the second set of user-supplied design requirements through the user interface.

3. The method of claim 1, wherein the method is performed without receiving user input between the first and second generative design processes.

4. The method of claim 1, wherein the second set of user-supplied design requirements is received in advance of executing the first generative design process.

5. The method of claim 1, further comprising:
performing a simulation on the first optimized geometry; and
applying a result of the simulation as an input to the second generative design process.

6. The method of claim 5, wherein the first generative design process, the simulation, and the second generative design process are performed according to a design recipe specified in advance of executing the first generative design process.

7. The method of claim 6, wherein the method is performed without receiving user input between the first and second generative design processes.

8. The method of claim 1, wherein the first optimized geometry is applied as a three-dimensional geometric design requirement for the second optimized geometry.

9. The method of claim 8, wherein the first optimized geometry is applied to limit the second optimized geometry to be wholly contained within the first optimized geometry.

10. The method of claim 1, wherein the first optimized geometry is used to seed the second generative design process.

11. The method of claim 2, wherein the second set of user-supplied design requirements comprises the first optimized geometry.

12. The method of claim 2, wherein intermediate results from computations performed during execution of the first generative design process are reused in the second generative design process to avoid repeating the computations.

13. The method of claim 2, wherein the first set of user-supplied design requirements and the second set of user-supplied design requirements have at least one common design requirement and at least one differing design requirement.

14. The computing system of claim 1, wherein the memory has instructions stored thereon that are executed by the at least one processor to cause the computing system to perform the method.

15. A non-transitory computer readable medium having instruction stored thereon, wherein the instructions are executed by the computing system of claim 1 to cause the computing system to perform the method.

16. A method performed by a computing system having at least one processor and a memory, the method comprising:
receiving a first set of optimization criteria for a computer aided design geometry;
generating a first optimized geometry using the received first set of optimization criteria;
receiving a second set of optimization criteria for the computer aided design geometry; and
generating a second optimized geometry using the generated first optimized geometry and the received second set of optimization criteria.

17. The method of claim 16, wherein the second set of optimization criteria are received through a computer user interface in response to the first optimized geometry being presented in the user interface.

18. The method of claim 17, further comprising:
performing a simulation on the first optimized geometry, wherein the second optimized geometry is generated further based on a result of the simulation.

19. The method of claim 16, wherein the first optimized geometry is applied as a three-dimensional geometric design requirement for generating the second optimized geometry.

20. The method of claim 16, wherein the first optimized geometry is applied to limit the second optimized geometry to be wholly contained within the first optimized geometry.
